(19) United States
(12) Patent Application Publication
(10) Pub. No.: US 2013/0169265 A1
(43) Pub. Date: Jul. 4, 2013

(54) VOLTAGE AMPLITUDE DETECTION CIRCUIT, INFORMATION STORAGE DEVICE, COMMUNICATION DEVICE, AND VOLTAGE AMPLITUDE DETECTION METHOD

(71) Applicant: Sony Corporation, Tokyo (JP)

(72) Inventors: Masahisa Tamura, Kanagawa (JP); Rie Hisamura, Kagoshima (JP)

(73) Assignee: Sony Corporation, Tokyo (JP)

(21) Appl. No.: 13/709,089

(22) Filed: Dec. 10, 2012

(30) Foreign Application Priority Data
Dec. 26, 2011 (JP) 2011-283413

(51) Int. Cl. G01R 25/00

(52) U.S. Cl. CPC G01R 25/00
USPC 324/76.77

(57) ABSTRACT

There is provided a voltage amplitude detection circuit including a first comparison unit configured to compare a voltage amplitude of an input signal with a predetermined voltage and output a comparison result; a first comparison result holding unit configured to hold the comparison result output from the first comparison unit in predetermined periods of a driving clock, and output the held comparison result; and a first comparison result evaluation unit configured to evaluate the comparison result output from the first comparison result holding unit in the predetermined periods of the driving clock and output an evaluation result.

### BACKGROUND

The present disclosure relates to a voltage amplitude detection circuit, an information storage device, a communication device, and a voltage amplitude detection method.

A number of clocks are used for electronic apparatuses. In order to detect failure of an electronic apparatus or control a system, it is necessary to detect the voltage amplitude of the clock. For example, JP 3107052B discloses a technology of a clock voltage amplitude detection circuit for detecting the voltage amplitude of a clock. In addition, a peak hold circuit is used for a conventional clock voltage amplitude detection circuit. This peak hold circuit is disclosed in JP 2002-135070A, for example.

### SUMMARY

However, in the conventional clock voltage amplitude detection circuit, passive elements such as resistors and capacitors are used for a peak hold circuit. Thus, when the frequency of a clock to be detected is low (e.g., about 100 kHz to 400 kHz), the time constant of the peak hold circuit should be increased. In addition, in order to increase the time constant of the peak hold circuit that uses passive elements, the resistance value and the capacitance value should be increased, with the result that the area could increase to a non-tolerable degree when considering mounting of the clock voltage amplitude detection circuit on an integrated circuit.

The present disclosure has been made in view of the foregoing problems, and provides a voltage amplitude detection circuit, an information processing device, a communication device, and a voltage amplitude detection method that are novel and improved and can be configured without using large capacitors or resistors even when the frequency of a clock to be detected is low, by omitting a peak hold circuit.

According to an embodiment of the present disclosure, there is provided a voltage amplitude detection circuit including a first comparison unit configured to compare a voltage amplitude of an input signal with a predetermined voltage and output a comparison result; a first comparison result holding unit configured to hold the comparison result output from the first comparison unit in predetermined periods of a driving clock, and output the held comparison result; and a first comparison result evaluation unit configured to evaluate the comparison result output from the first comparison result holding unit in the predetermined periods of the driving clock and output an evaluation result.

According to another embodiment of the present disclosure, there is provided an information processing device including the voltage amplitude detection circuit.

According to still another embodiment of the present disclosure, there is provided a communication device including the voltage amplitude detection circuit.

According to yet another embodiment of the present disclosure, there is provided a voltage amplitude detection method including comparing a voltage amplitude of an input signal with a predetermined voltage and output a comparison result; holding a comparison result output in the comparison step in predetermined periods of a driving clock, and output the held comparison result; and evaluating a comparison result output in the comparison result holding step in the predetermined periods of the driving clock, and output an evaluation result.

According to the embodiments of the present disclosure described above, it is possible to provide a voltage amplitude detection circuit, an information processing device, a communication device, and a voltage amplitude detection method that are novel and improved and can be configured without using large capacitors or resistors even when the frequency of a clock to be detected is low, by omitting a peak hold circuit.

### BRIEF DESCRIPTION OF THE DRAWINGS

FIG. 1 is an illustration diagram showing the configuration of a conventional voltage amplitude detection circuit 1000;

FIG. 2 is an illustration diagram showing an exemplary circuit configuration of a peak hold circuit 1001 used in the conventional voltage amplitude detection circuit 1000;

FIG. 3 is an illustration diagram showing the functional configuration of a voltage amplitude detection circuit 100 according to a first embodiment of the present disclosure;

FIG. 4 is an illustration diagram showing a specific exemplary circuit configuration of the voltage amplitude detection circuit 100 according to the first embodiment of the present disclosure shown in FIG. 3;

FIG. 5 is an illustration diagram showing a timing chart of a signal supplied to the voltage amplitude detection circuit 100 shown in FIG. 4;

FIG. 6 is an illustration diagram showing a timing chart of a signal supplied to the voltage amplitude detection circuit 100 shown in FIG. 4;

FIG. 7 is an illustration diagram showing a specific exemplary circuit configuration of a voltage amplitude detection circuit 200 according to a second embodiment of the present disclosure;

FIG. 8 is an illustration diagram showing a timing chart of a signal supplied to the voltage amplitude detection circuit 200 shown in FIG. 7;

FIG. 9 is an illustration diagram showing a timing chart of a signal supplied to the voltage amplitude detection circuit 200 shown in FIG. 7;

FIG. 10 is an illustration diagram showing a specific exemplary circuit configuration of a voltage amplitude detection circuit 200′ according to a variation of the second embodiment of the present disclosure;

FIG. 11 is an illustration diagram showing a timing chart of a signal supplied to the voltage amplitude detection circuit 200′ shown in FIG. 10;

FIG. 12 is an illustration diagram showing an exemplary configuration of a delay circuit 214′ of the voltage amplitude detection circuit 200′ shown in FIG. 10;

FIG. 13 is an illustration diagram showing a specific exemplary circuit configuration of a voltage amplitude detection circuit 300 according to a third embodiment of the present disclosure;

FIG. 14 is an illustration diagram showing a timing chart of a signal supplied to the voltage amplitude detection circuit 300 shown in FIG. 13;

FIG. 15 is an illustration diagram showing a timing chart of a signal supplied to the voltage amplitude detection circuit 300 shown in FIG. 13;

FIG. 16 is an illustration diagram showing a specific exemplary circuit configuration of a voltage amplitude detection circuit 400 according to a fourth embodiment of the present disclosure;

FIG. 17 is an illustration diagram showing a timing chart of a signal supplied to the voltage amplitude detection circuit 400 shown in FIG. 16;

FIG. 18 is an illustration diagram showing a timing chart of a signal supplied to the voltage amplitude detection circuit 400 shown in FIG. 16;

FIG. 19 is an illustration diagram showing the configuration of a voltage amplitude detection circuit 500 according to a fifth embodiment of the present disclosure;

FIG. 20 is an illustration diagram showing a timing chart of a signal supplied to the voltage amplitude detection circuit 500 shown in FIG. 19;

FIG. 21 is an illustration diagram showing a specific exemplary circuit configuration of a voltage amplitude detection circuit 600 according to a sixth embodiment of the present disclosure;

FIG. 22 is an illustration diagram showing a timing chart of a signal supplied to a voltage amplitude detection circuit 600 shown in FIG. 21;

FIG. 23 is an illustration diagram showing the functional configuration of a storage device 700 having a voltage amplitude detection circuit according to each embodiment; and

FIG. 24 is an illustration diagram showing the functional configuration of a communication device 800 having a voltage amplitude detection circuit according to each embodiment.

### DETAILED DESCRIPTION OF THE EMBODIMENTS

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

The description will be made in the following order.

<1. Configuration of Conventional Voltage Amplitude Detection Circuit>

<2. First Embodiment>

[Exemplary Functional Configuration of Voltage Amplitude Detection Circuit]

[Exemplary Circuit Configuration of Voltage Amplitude Detection Circuit]

[Operation of Voltage Amplitude Detection Circuit]

<3. Second Embodiment>

[Exemplary Circuit Configuration of Voltage Amplitude Detection Circuit]

[Operation of Voltage Amplitude Detection Circuit]

[Variations]

<4. Third Embodiment>

[Exemplary Circuit Configuration of Voltage Amplitude Detection Circuit]

[Operation of Voltage Amplitude Detection Circuit]

<5. Fourth Embodiment>

[Exemplary Circuit Configuration of Voltage Amplitude Detection Circuit]

[Operation of Voltage Amplitude Detection Circuit]

<6. Fifth Embodiment>

[Exemplary Circuit Configuration of Voltage Amplitude Detection Circuit]

[Operation of Voltage Amplitude Detection Circuit]

<7. Sixth Embodiment>

[Exemplary Circuit Configuration of Voltage Amplitude Detection Circuit]

[Operation of Voltage Amplitude Detection Circuit]

<8. Examples of Application of Voltage Amplitude Detection Circuit>

<9. Conclusion>

### 1. Configuration of Conventional Voltage Amplitude Detection Circuit

First, before describing preferred embodiments of the present disclosure in detail, the configuration of a conventional voltage amplitude detection circuit and problems thereof will be described.

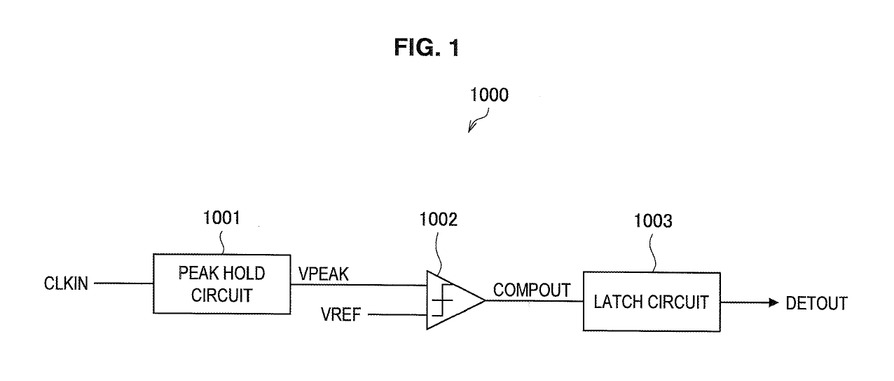

FIG. 1 is an illustration diagram showing the configuration of a conventional voltage amplitude detection circuit 1000, and shows a circuit configuration disclosed in JP 3107052B. As shown in FIG. 1, the conventional voltage amplitude detection circuit 1000 includes a peak hold circuit 1001, a voltage detection circuit 1002, and a latch circuit 1003.

The peak hold circuit 1001 holds the peak value of an input signal CLKIN. The voltage detection circuit 1002 compares an output voltage VPEAK of the peak hold circuit 1001 with a predetermined reference voltage VREF and outputs an output signal COMPOUT. The latch circuit 1003 holds the output signal COMPOUT output from the voltage detection circuit 1002, and outputs a detection output DETOUT.

The conventional voltage amplitude detection circuit 1001 can, by having the configuration shown in FIG. 1, detect if the voltage amplitude of the input signal CLKIN is higher than the reference voltage VREF, and output a detection result.

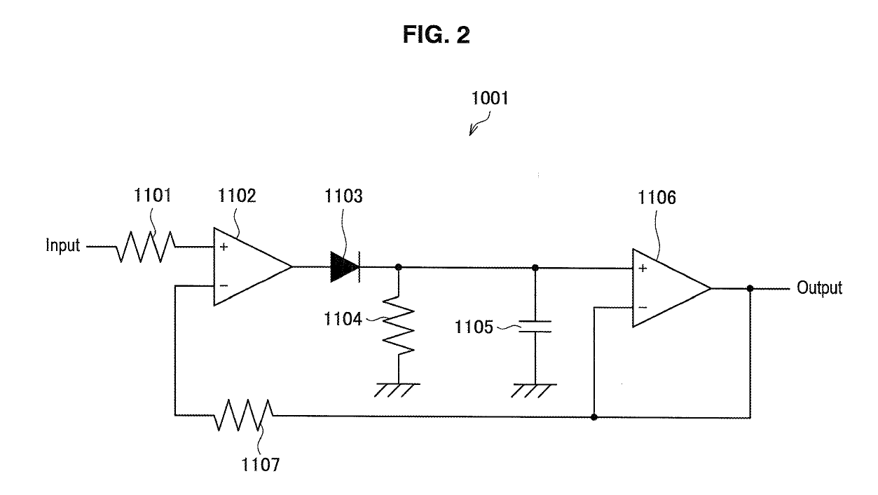

FIG. 2 is an illustration diagram showing an exemplary circuit configuration of a peak hold circuit 1001 used for the conventional voltage amplitude detection circuit 1000, and shows a circuit configuration disclosed in JP 2002-135070B. As shown in FIG. 2, the peak hold circuit 1001 used for the conventional voltage amplitude detection circuit 1000 includes an input resistor 1101, a feedback resistor 1107, a first operational amplifier 1102, a diode 1103, a resistor 1104, a capacitor 1105, and a second operational amplifier 1106.

The operation of the peak hold circuit 1001 shown in FIG. 2 will be briefly described. When an input signal VIN that is higher than a past peak output voltage VOUT arrives from the Input, the capacitor 105 is charged via the diode 1103. When the capacitor 1105 is charged, an output voltage VOUT from the Output increases. When an input signal does not arrive at the Input, electrical charges accumulated in the capacitor 1105 are discharged via the resistor 1104, and an output voltage VOUT from the Output decreases. The peak hold circuit 1001 can hold the peak value of an input voltage by operating in this manner.

A time constant formed by the resistor 1104 and the capacitor 1105 included in the peak hold circuit 1001 should be adequately set according the properties of a signal to be detected. When the frequency of a clock to be detected is low, the time constant formed by the resistor 1104 and the capacitor 1105 should be increased, and the resistance value and the capacitance value therefor should be increased.

However, an increase in the resistance value and the capacitance value would, when mounting the voltage amplitude detection circuit on an integrated circuit is considered, increase to an extent that an increase in the circuit area is non-tolerable. Thus, when mounting such a voltage amplitude detection circuit on an integrated circuit is considered, it is desirable that a circuit such as a peak hold circuit that uses passive elements be not used.

Thus, the following embodiments of the present disclosure describe a technology that can adequately detect the voltage amplitude of an input clock without using a circuit like a peak hold circuit that uses passive elements, even when the frequency of a clock to be detected is low.

### 2. First Embodiment

### Exemplary Functional Configuration of Voltage Amplitude Detection Circuit

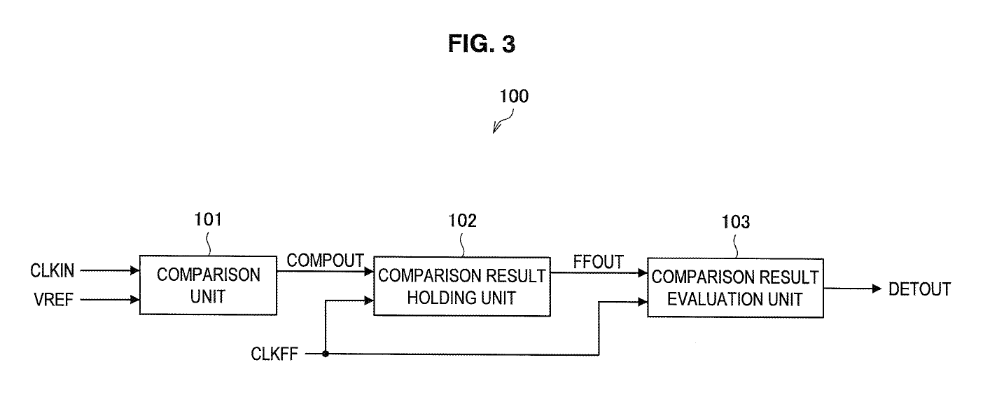

FIG. 3 is an illustration diagram showing the functional configuration of a voltage amplitude detection circuit 100 according to a first embodiment of the present disclosure. Hereinafter, the functional configuration of the voltage amplitude detection circuit 100 according to the first embodiment of the present disclosure will be described with reference to FIG. 3.

As shown in FIG. 3, the voltage amplitude detection circuit 100 according to the first embodiment of the present disclosure includes a comparison unit 101, a comparison result holding unit 102, and a comparison result evaluation unit 103.

The comparison unit 101 compares the voltage amplitude of an input clock CLKIN with a predetermined reference voltage VREF. The comparison result 101 outputs a comparison result of the voltage amplitude of the input clock CLKIN and the predetermined reference voltage VREF to the comparison result holding unit 102. Specifically, the comparison unit 101 compares the voltage amplitude of the input clock CLKIN with the predetermined reference voltage VREF, and outputs a predetermined signal COMPOUT at high level in the period in which the voltage amplitude of the input clock CLKIN is higher than the predetermined reference voltage VREF.

The comparison result holding unit 102 captures the signal COMPOUT sent from the comparison unit 101 at a rising edge of a clock signal CLKFF, and outputs the signal as a predetermined signal FFOUT to the comparison result evaluation unit 103. The comparison result holding unit 102, by capturing the signal COMPOUT at a rising edge of the clock signal CLKFF, outputs a signal FFOUT at high level if the voltage amplitude of the input clock CLKIN is higher than the predetermined reference voltage VREF, and outputs a signal FFOUT at low level if the voltage amplitude of the input clock CLKIN is not higher than the predetermined reference voltage VREF.

The comparison result evaluation unit 103 captures the signal FFOUT output from the comparison result holding unit 102, evaluates the content of the signal FFOUT on the basis of the clock signal CLKFF, and outputs the evaluation result as a signal DETOUT. The comparison result evaluation unit 103 can, by evaluating the content of the signal FFOUT on the basis of the clock signal CLKFF, accurately determine if the voltage amplitude of the input clock CLKIN is higher than the predetermined reference voltage VREF.

The functional configuration of the voltage amplitude detection circuit 100 according to the first embodiment of the present disclosure has been described with reference to FIG. 3. Next, a specific exemplary circuit configuration of the voltage amplitude detection circuit 100 according to the first embodiment of the present disclosure shown in FIG. 3 will be described.

### [Exemplary Circuit Configuration of Voltage Amplitude Detection Circuit]

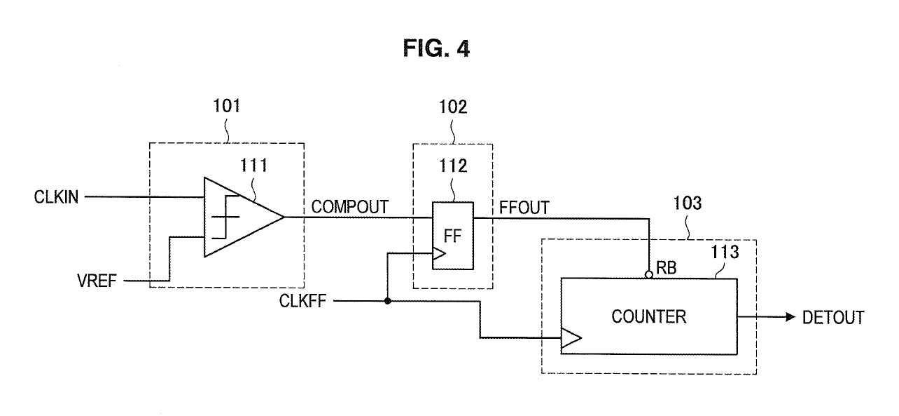

FIG. 4 is an illustration diagram showing a specific exemplary circuit configuration of the voltage amplitude detection circuit 100 according to the first embodiment of the present disclosure shown in FIG. 3. Hereinafter, a specific exemplary circuit configuration of the voltage amplitude detection circuit 100 according to the first embodiment of the present disclosure will be described with reference to FIG. 4.

As shown in FIG. 4, the voltage amplitude detection circuit 100 according to the first embodiment of the present disclosure includes a comparator 111, a flip-flop 112, and a counter 113.

The comparator 111 constitutes the comparison unit 101 in FIG. 3, and compares the voltage amplitude of an input clock CLKIN with a predetermined reference voltage VREF. The comparator 111 compares the voltage amplitude of the input clock CLKIN with the predetermined reference voltage VREF, and outputs a predetermined signal COMPOUT at high level in the period in which the voltage amplitude of the input clock CLKIN is higher than the predetermined reference voltage VREF.

The flip-flop 112 constitutes the comparison result holding unit 102 in FIG. 3, and captures the signal COMPOUT sent from the comparator 111 at a rising edge of a clock signal CLKFF. The flip-flop 112 outputs the captured signal COMPOUT as a predetermined signal FFOUT. The clock signal CFKFF that drives the flip-flop 112 has the same frequency as the input clock CLKIN, and has a phase adjusted so that the clock signal CFKFF has a phase difference of 90° from the input clock CLKIN. Thus, the flip-flop 112, when the input clock CLKIN has reached a predetermined amplitude, captures the output signal COMPOUT of the comparator 111 in the period in which the output signal COMPOUT is at high level, and always outputs a signal FFOUT at high level. The flip-flop 112, by capturing the signal COMPOUT at a rising edge of the clock signal CLKFF, outputs a signal FFOUT at high level if the voltage amplitude of the input clock CLKIN is higher than the predetermined reference voltage VREF, and outputs a signal FFOUT at low level if the voltage amplitude of the input clock CLKIN is not higher than the predetermined reference voltage VREF.

The counter 113 constitutes the comparison result evaluation unit 103 in FIG. 3, and captures the signal FFOUT output from the flip-flop 112 and evaluates the content of the signal FFOUT on the basis of the clock signal CLKFF. Specifically, the counter 113 that operates by being supplied with the clock signal CLKFF starts a counting operation when the signal FFOUT becomes high level and, after counting a predetermined number of times, outputs the evaluation result of the signal FFOUT as a signal DETOUT. The counter 113 can, by evaluating the content of the signal FFOUT on the basis of the clock signal CLKFF, accurately determine if the voltage amplitude of the input clock CLKIN is higher than the predetermined reference voltage VREF.

A specific exemplary circuit configuration of the voltage amplitude detection circuit 100 according to the first embodiment of the present disclosure has been described with reference to FIG. 4. Next, the operation of the voltage amplitude detection circuit 100 according to the first embodiment of the present disclosure will be described.

### [Operation of Voltage Amplitude Detection Circuit]

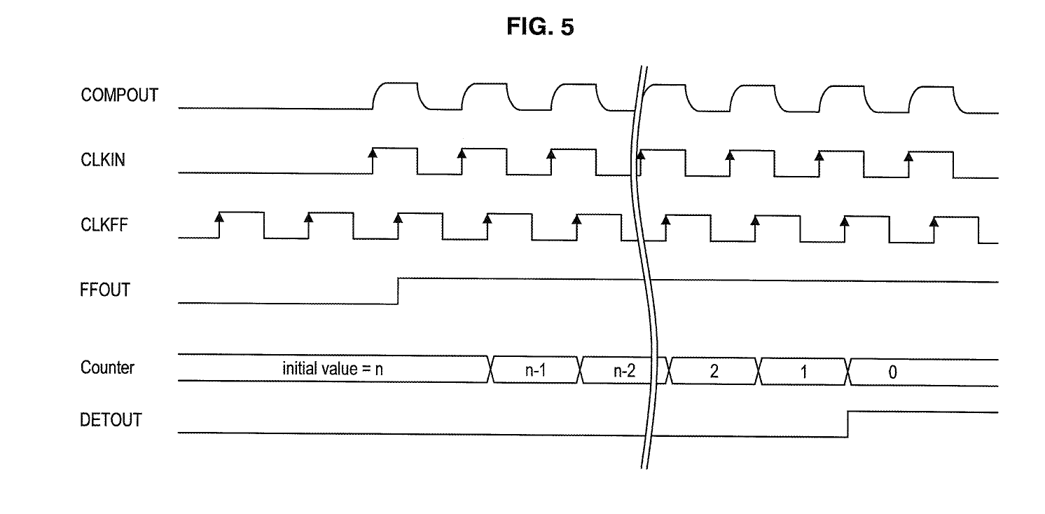

FIG. 5 is an illustration diagram showing a timing chart of a signal supplied to the voltage amplitude detection circuit 100 shown in FIG. 4. Hereinafter, the operation of the voltage amplitude detection circuit 100 according to the first embodiment of the present disclosure will be described with reference to FIG. 5.

Unless an input clock CLKIN is supplied to the voltage amplitude detection circuit 100, or even when an input clock CLKIN is supplied, if the voltage amplitude thereof is below that of a predetermined reference voltage VREF, the comparator 111 compares the voltage amplitude of the input clock CLKIN with the predetermined reference voltage VREF and, as the voltage amplitude of the reference voltage VREF is higher, outputs a signal COMPOUT at low level.

The flip-flop 112 outputs the content of the signal COMPOUT output from the comparator 111 as a signal FFOUT at a rising edge of the clock CLKFF. Upon being supplied with the signal COMPOUT at low level, the flip-flop 112 outputs a signal FFOUT at low level.

The counter 113 has an initial value n, and operates upon being supplied with the clock CLKFF. The counter 113 counts down the count value if the signal FFOUT is at high level at a rising edge of the clock CLKFF, and resets the count value to the initial value if the signal FFOUT is at low level. When the voltage amplitude detection circuit 100 is not supplied with the input clock CLKIN, the signal FFOUT is at low level. Thus, the count value of the counter 113 remains the initial value n.

When the voltage amplitude detection circuit 100 is supplied with an input clock CLKIN with a voltage amplitude higher than the reference voltage VREF, the comparator 111 compares the voltage amplitude of the input clock CLKIN with the predetermined reference voltage VREF and, as the voltage amplitude of the input clock CLKIN is higher, outputs a signal COMPOUT at high level.

The flip-flop 112, upon being supplied with the signal COMPOUT at high level, captures the signal COMPOUT at the timing of a rising edge of the CLKFF, and outputs a signal FFOUT at high level.

The counter 113, upon being supplied with the signal FFOUT at high level, counts down the count value at the timing of a rising edge of the clock CLKFF. Then, when the count value of the counter 113 has become zero, the counter 113 outputs a signal DETOUT at high level. As the signal DETOUT is at high level, it can be identified that an input clock CLKIN with a voltage amplitude higher than the reference voltage VREFF has been supplied. Note that the counter 113 may be an up counter. If the counter 113 is an up-counter, the counter 113 may output a signal DETOUT at high level at a point in time when the counter value has reached a predetermined value.

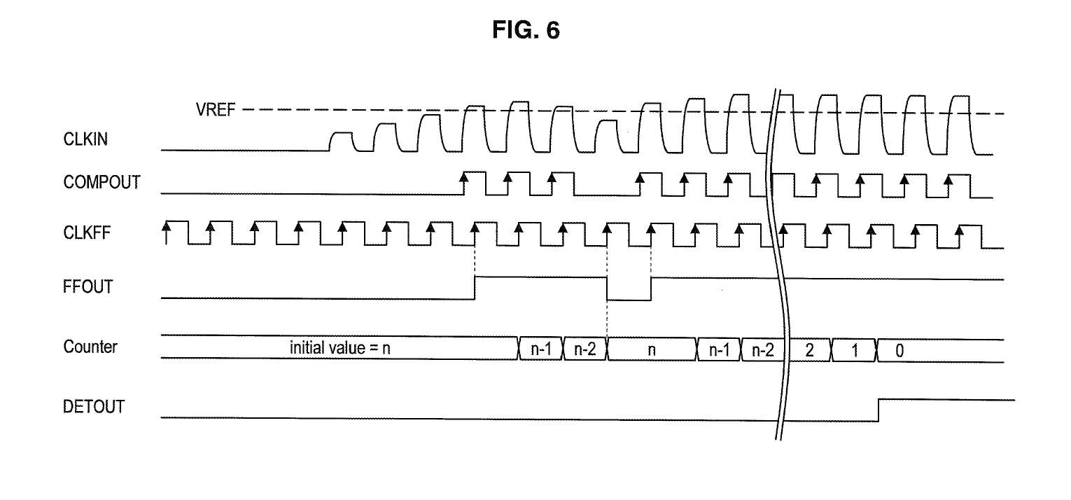

When an input clock CLKIN is stably supplied to the voltage amplitude detection circuit 100 as described above, the voltage amplitude of the clock is always higher than the reference voltage VREF. However, a case is considered in which, immediately after a clock is generated, a stable clock is not supplied to the voltage amplitude detection circuit 100. FIG. 6 is an illustration diagram showing a timing chart of a signal supplied to the voltage amplitude detection circuit 100 shown in FIG. 4, and shows a view in which the voltage amplitude of the input clock CLKIN is not stable.

As shown in FIG. 6, at the beginning of when an input clock CLKIN is supplied to the voltage amplitude detection circuit 100, if the voltage amplitude thereof is not higher than the reference voltage VREF, the count value of the counter 113 does not decrease. After that, when the voltage amplitude of the input clock CLKIN becomes higher than the reference voltage VREF, the count value of the counter 113 starts to decrease from n.

However, when the voltage amplitude of the input clock CLKIN becomes lower than the reference voltage VREF, the comparator 111 outputs a signal COMPOUT at low level. Then, when the signal COMPOUT is at low level at a rising edge of the clock CLKFF, the flip-flop 112 outputs a signal FFOUT at low level. The counter 113, upon being supplied with the signal FFOUT at low level, resets the count value to n at a rising edge of the clock CLKF.

After that, when the voltage amplitude of the input clock CLK becomes higher than the reference voltage VREF, the count value of the counter 113 starts to decrease from n, and when the count value of the counter 113 has become zero, the counter 113 outputs a signal DETOUT at high level.

When the voltage amplitude detection circuit 100 operates by being supplied with the input clock CLKIN as described above, even if the frequency of a clock to be detected is low (e.g., about 100 kHz to 400 kHz), it is possible to accurately detect generation of the clock without using a peak hold circuit that uses passive elements. As a flip-flop is used without using passive elements, mounting of the voltage amplitude detection circuit 100 on an integrated circuit can be facilitated. In addition, as a counter is operated for a given period of time using a held signal as a start signal and the output of the counter is used as a determination result, it is possible to eliminate detection errors by not outputting a detection result unless a stable clock is input.

### 3. Second Embodiment

### Exemplary Circuit Configuration of Voltage Amplitude Detection Circuit

In the aforementioned first embodiment of the present disclosure, a predetermined clock CLKFF is supplied to the flip-flop 112 and the counter 113. If the clock supplied to the flip-flop and the counter is generated from a signal output from the comparator, it becomes possible to further suppress the circuit scale.

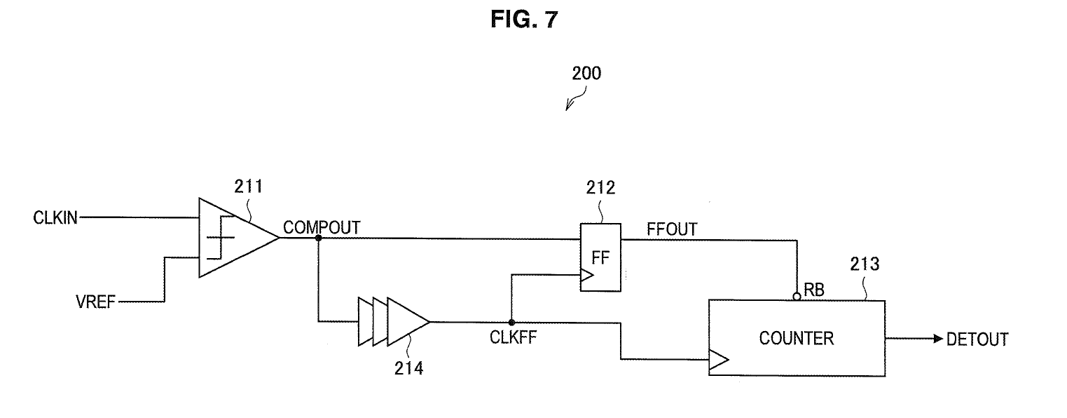

FIG. 7 is an illustration diagram showing a specific exemplary circuit configuration of a voltage amplitude detection circuit 200 according to the second embodiment of the present disclosure. Hereinafter, a specific exemplary circuit configuration of the voltage detection circuit 200 according to the second embodiment of the present disclosure will be described with reference to FIG. 7.

As shown in FIG. 7, the voltage amplitude detection circuit 200 according to the second embodiment of the present disclosure includes a comparator 211, a flip-flop 212, a counter 213, and a delay circuit 214.

The comparator 211, like the comparator 111 shown in FIG. 4, compares the voltage amplitude of an input clock CLKIN with a predetermined reference voltage VREF. The comparator 211 compares the voltage amplitude of the input clock CLKIN with the predetermined reference voltage VREF, and outputs a predetermined signal COMPOUT at high level in the period in which the voltage amplitude of the input clock CLKIN is higher than the predetermined reference voltage VREF.

The flip-flop 212, like the flip-flop 112 shown in FIG. 4, captures the signal COMPOUT sent from the comparator 211 at a rising edge of a clock signal CLKFF. The flip-flop 212, by capturing the signal COMPOUT at a rising edge of the clock signal CLKFF, outputs a signal FFOUT at high level if the voltage amplitude of the input clock CLKIN is higher than the reference voltage VREF, and outputs a signal FFOUT at low level if the voltage amplitude of the input clock CLKIN is not higher than the predetermined reference voltage VREF. In this embodiment, the clock signal CLKFF is generated from the signal COMPOUT sent from the comparator 211.

The counter 213, like the counter 113 shown in FIG. 4, captures the signal FFOUT output from the flip-flop 212, and evaluates the content of the signal FFOUT on the basis of the clock signal CLKFF. Specifically, the counter 213 that operates upon being supplied with the clock signal CLKFF starts a counting operation when the signal FFOUT becomes high level and, after counting a predetermined number of times, outputs the evaluation result of the signal FFOUT as a signal DETOUT. The counter 213 can, by evaluating the content of the signal FFOUT on the basis of the clock signal CLKFF, more accurately determine if the voltage amplitude of the input clock CLKIN is higher than the predetermined reference voltage VREF. In this embodiment, the clock signal CLKFF is generated from the signal COMPOUT sent from the comparator 211.

The delay circuit 214 delays the output of the comparator 211 by a predetermined time, and outputs the delayed signal as a signal FFOUT. In this embodiment, the delay circuit 214 outputs a signal CLKFF by delaying the output of the comparator 211 so that the output signal FFOUT has a phase difference of 90° from the signal COMPOUT output from the comparator 211.

Hereinabove, a specific exemplary circuit configuration of the voltage amplitude detection circuit 200 according to the second embodiment of the present disclosure has been described with reference to FIG. 7. Next, the operation of the voltage amplitude detection circuit 200 according to the second embodiment of the present disclosure will be described.

### [Operation of Voltage Amplitude Detection Circuit]

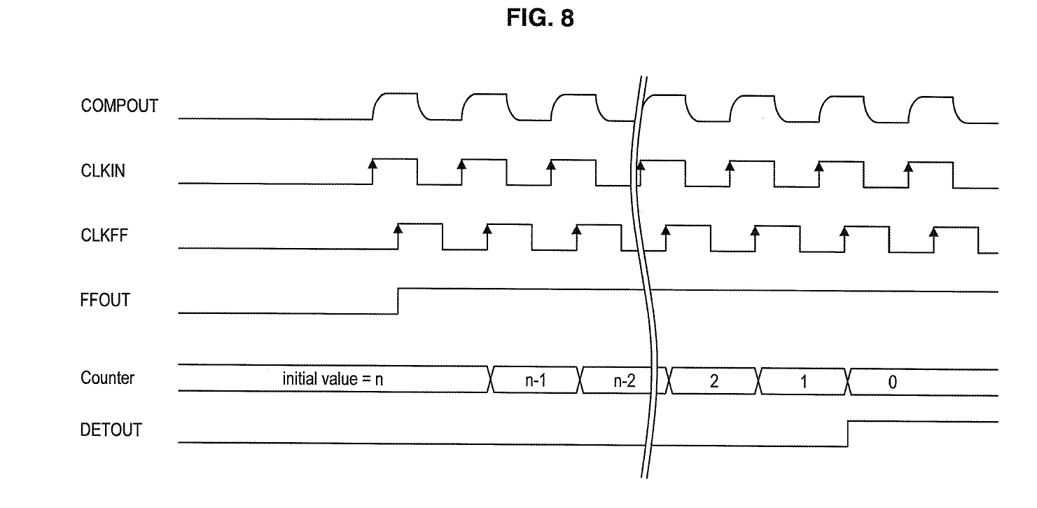

FIG. 8 is an illustration diagram showing a timing chart of a signal supplied to the voltage amplitude detection circuit 200 shown in FIG. 7. Hereinafter, the operation of the voltage amplitude detection circuit 200 according to the second embodiment of the present disclosure will be described with reference to FIG. 8.

Unless an input clock CLKIN is supplied to the voltage amplitude detection circuit 200, or even when an input clock CLKIN is supplied, if the voltage amplitude thereof is lower than a predetermined reference voltage VREF, the comparator 211 compares the voltage amplitude of the input clock CLKIN with the predetermined reference voltage VREF, and outputs a signal COMPOUT at low level as the voltage amplitude of the reference voltage VREF is higher. As the signal COMPOUT is at low level, the signal CLKFF output from the delay circuit 214 is also at low level.

The flip-flop 212, as the signal CLKFF remains at low level, does not output the content of the signal COMPOUT output from the comparator 111, and outputs a signal FFOUT at low level. The counter 213 has an initial value n, and operates by being supplied with the clock CLKFF. When the signal FFOUT is at high level at the timing of a rising edge of the clock CLKFF, the counter 213 counts down the count value, and when the signal FFOUT is at low level, the counter 213 resets the count value to the initial value. However, unless the input clock CLKIN is supplied to the voltage amplitude detection circuit 200, the signal CLKFF remains at low level. Thus, the counter 213 does not operate and the count value remains the initial value n.

When the voltage amplitude detection circuit 200 is supplied with an input clock CLKIN with a voltage amplitude higher than the reference voltage VREF, the comparator 211 compares the voltage amplitude of the input clock CLKIN with the predetermined reference voltage VREF and, as the voltage amplitude of the input clock CLKIN is higher, outputs a signal COMPOUT at high level in the period in which the voltage amplitude of the input clock CLKIN is higher. When the signal COMPOUT, which is at high level in the period in which the voltage amplitude of the input clock CLKIN is higher, is supplied to the delay circuit 214, the signal CLKFF becomes a signal having a phase difference of 90° from the signal COMPOUT.

The flip-flop 212, upon being supplied with the signal COMPOUT at high level, captures the signal COMPOUT at the timing of a rising edge of the signal CLKFF, and outputs a signal FFOUT at high level.

The counter 213, upon being supplied with the signal FFOUT at high level, counts down the count value at the timing of a rising edge of the signal CLKFF. Then, when the count value of the counter 213 has become zero, the counter 213 outputs a signal DETOUT at high level. When the signal DETOUT is at high level, it can be identified that an input clock CLKIN with a voltage amplitude higher than the reference voltage VREF has been supplied. Note that the counter 213 may be an up-counter. When the counter 213 is an up-counter, the counter 213 may output a signal DETOUT at high level at a point in time when the count value has reached a predetermined value.

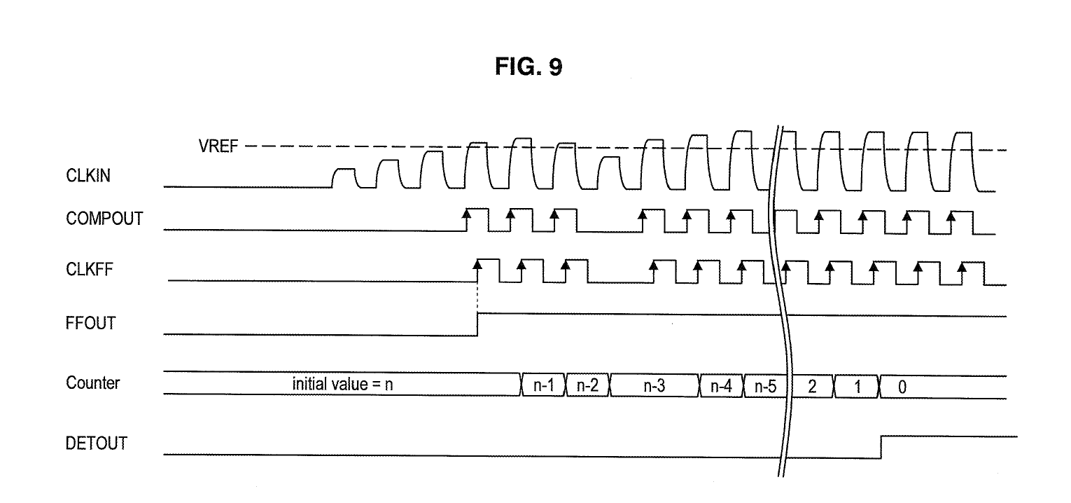

When an input clock CLKIN is stably supplied to the voltage amplitude detection circuit 200 as described above, the voltage amplitude of the clock is always higher than the reference voltage VREF. However, a case is considered in which, immediately after a clock is generated, a stable clock is not supplied to the voltage amplitude detection circuit 200. FIG. 9 is an illustration diagram showing a timing chart of a signal supplied to the voltage amplitude detection circuit 200 shown in FIG. 7, and shows a view in which the voltage amplitude of the input clock CLKIN is not stable.

As shown in FIG. 9, at the beginning of when the input clock CLKIN is supplied to the voltage amplitude detection circuit 200, if the voltage amplitude thereof is not higher than the reference voltage VREF, the count value of the counter 213 does not decrease. After that, when the voltage amplitude of the input clock CLKIN becomes higher than the reference voltage VREF, the count value of the counter 213 starts to decrease from n.

However, when the voltage amplitude of the input clock CLKIN becomes lower than the reference voltage VREF, the comparator 211 outputs a signal COMPOUT at low level. When the output of the signal COMPOUT becomes low level, a signal CLKFF generated from the signal COMPOUT also becomes low level. As the signal CLKFF becomes low level, the count value of the counter 213 is maintained (the count value remains n−3 in FIG. 9).

After that, when the voltage amplitude of the input clock CLKIN becomes higher than the reference voltage VREF, the count value of the counter 213 starts to decrease from n−3, and when the count value of the counter 213 has become zero, the counter 213 outputs a signal DETOUT at high level. Accordingly, the count value of the counter 213 may be set to be a length that is long enough to wait until the input clock CLKIN is stabilized.

When the voltage amplitude detection circuit 200 operates by being supplied with the input clock CLKIN as described above, even if the frequency of a clock to be detected is low, it is possible to detect generation of the clock without using a peak hold circuit that uses passive elements, like the voltage amplitude detection circuit 100 according to the first embodiment. As a flip-flop is used without using passive elements, mounting of the voltage amplitude detection circuit 200 on an integrated circuit can be facilitated. In addition, when the counter is operated for a given period of time using a held signal as a start signal and the output of the counter is used as a determination result, it is possible to eliminate detection errors by not outputting a detection result unless a stable clock is input. In addition, when the voltage amplitude detection circuit 200 according to the second embodiment of the present disclosure generates a signal CLKFF to be supplied to the flip-flop 212 and the counter 213 from the output COMPOUT of the comparator 211, it becomes unnecessary to prepare a dedicated clock. Thus, a further reduction in the size of the voltage amplitude detection circuit 200 can be achieved as compared to the voltage amplitude detection circuit 100 according to the first embodiment.

Although this embodiment shows an example in which the phase difference between the input clock CLKIN and the signal CLKFF is about 90°, the present disclosure is not limited thereto. The phase difference can be any value as long as it can surely capture a portion of the input signal waveform that is necessary to determine the voltage amplitude and can assure a phase relationship that can avoid metastability of the flip-flop.

### [Variation]

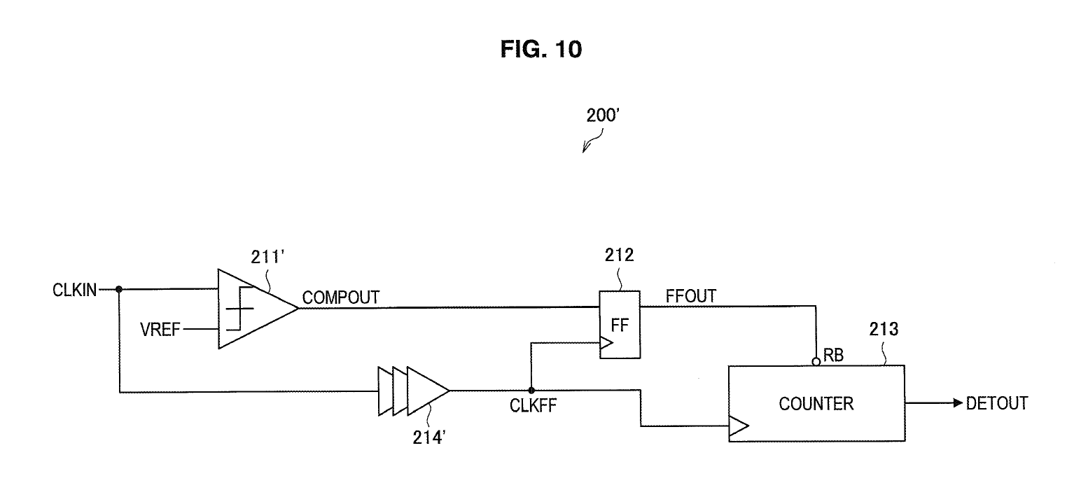

Although the aforementioned voltage amplitude detection circuit 200 generates a clock to operate the flip-flop 212 and the counter 213 by delaying the signal COMPOUT output from the comparator 211 by a predetermined time at the delay circuit 214, it is also possible to generate a clock to operate the flip-flop 212 and the counter 213 by delaying the input clock CLKIN by a predetermined time. FIG. 10 is an illustration diagram showing a specific exemplary circuit configuration of a voltage amplitude detection circuit 200′ according to a variation of the second embodiment of the present disclosure.

The voltage amplitude detection circuit 200′ shown in FIG. 10 differs from the voltage amplitude detection circuit 200 shown in FIG. 7 in that a signal input to a delay circuit 214′ is an input clock CLKIN and a signal CLKFF is generated from the input clock CLKIN. In addition, the delay circuit 214′ amplifies the input clock CLKIN by a predetermined amount to use the input clock CLKIN as a clock to operate the flip-flop 212 and the counter 213. Functions other than such points are about the same as the functions of the voltage amplitude detection circuit 200 shown in FIG. 7.

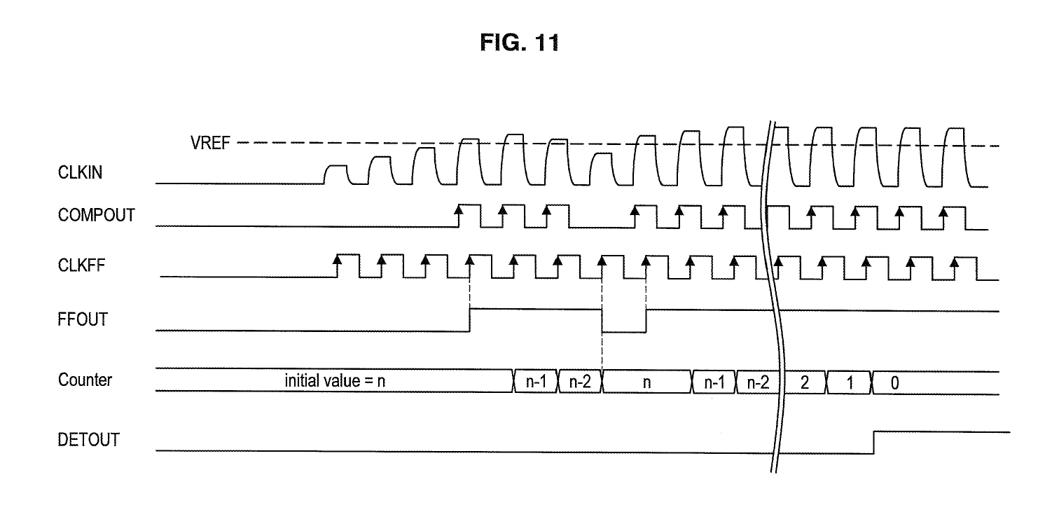

FIG. 11 is an illustration diagram showing a timing chart of a signal supplied to the voltage amplitude detection circuit 200′ shown in FIG. 10, and shows a view in which the voltage amplitude of the input clock CLKIN is not stable.

As shown in FIG. 11, at the beginning of when the input clock CLKIN is supplied to the voltage amplitude detection circuit 200′, if the voltage amplitude thereof is not higher than the reference voltage VREF, the count value of the counter 213 does not decrease. After that, when the voltage amplitude of the input clock CLKIN becomes higher than the reference voltage VREF, the count value of the counter 213 starts to decrease from n.

However, when the voltage amplitude of the input clock CLKIN becomes lower than the reference voltage VREF, the comparator 211 outputs a signal COMPOUT at low level. Even when the voltage amplitude of the input clock CLKIN is lower than the reference voltage VREF, the signal CLKFF continues to be generated as the input clock CLKIN is supplied. In addition, when the signal COMPOUT is at low level at a rising edge of the signal CLKFF, the flip-flop 212 outputs a signal FFOUT at low level. The counter 213, upon being supplied with the signal FFOUT at low level, resets the count value to n at a rising edge of the clock CLK.

After that, when the voltage amplitude of the input clock CLKIN becomes higher than the reference voltage VREF again, the count value of the counter 213 starts to decrease from n, and when the count value of the counter 213 has become zero, the counter 213 outputs a signal DETOUT at high level.

As described above, even when a clock to operate the flip-flop 212 and the counter 213 is generated by delaying the input clock CLKIN by a predetermined time, it is possible to adequately detect the voltage amplitude of the input clock CLKIN.

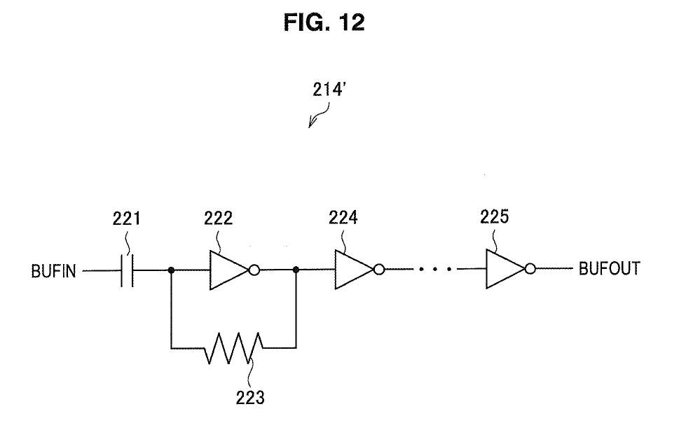

FIG. 12 is an illustration diagram showing an exemplary configuration of the delay circuit 214′ of the voltage amplitude detection circuit 200′ shown in FIG. 10. As shown in FIG. 12, the delay circuit 214′ includes, for example, a capacitor 221, inverters 222, 224, and 225, and a resistance feedback circuit 223.

The capacitor 221 cuts the DC components of an input signal BURN. The inverter 222 is connected in parallel with the resistance feedback circuit 223, and amplifies the input signal whose DC components have been cut with the capacitor 221, by a predetermined amount. The resistance feedback circuit 223 has an effect of supplying a bias voltage, which is equal to the threshold voltage of the inverter 222, to the input signal. The inverters 224 and 225 that are connected in cascade amplify and delay the output signal of the inverter 222. The number of inverters may be adequately set according to the amount of amplification, delay time, and the like that are necessary.

### 4. Third Embodiment

### Exemplary Circuit Configuration of Voltage Amplitude Detection Circuit

In the aforementioned second embodiment of the present disclosure, a further reduction in size of the voltage amplitude detection circuit is achieved by generating a signal CLKFF to be supplied to the flip-flop 212 and the counter 213 from the output COMPOUT of the comparator 211. However, with a method of delaying the output of the comparator 211 using a delay circuit, there may be cases in which the phase difference between a signal input to a flip-flop and a clock is not accurately maintained depending on the operation environment. Thus, in the second embodiment of the present disclosure, a voltage amplitude detection circuit will be described that has an objective of accurately maintaining the phase difference between a signal input to the flip-flop and a clock by causing the output of the comparator to branch using a frequency divider.

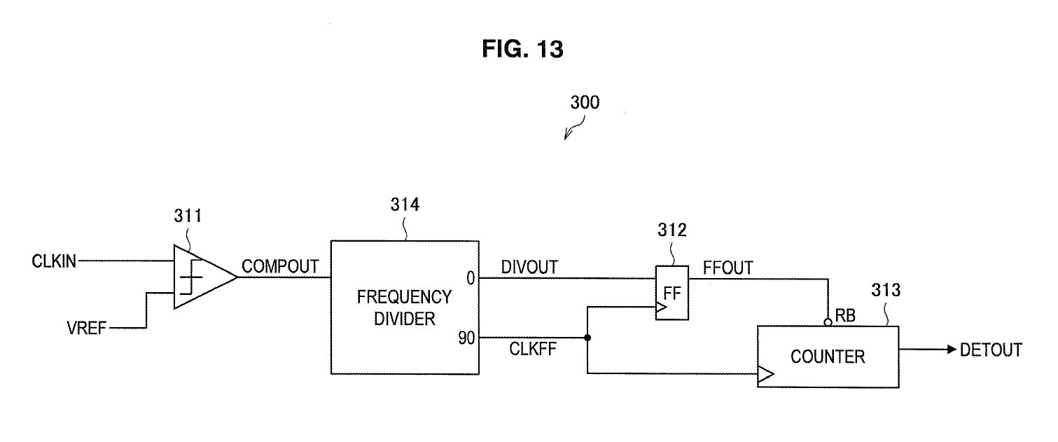

FIG. 13 is an illustration diagram showing a specific exemplary circuit configuration of the voltage amplitude detection circuit 300 according to a third embodiment of the present disclosure. Hereinafter, a specific exemplary circuit configuration of the voltage amplitude detection circuit 300 according to the third embodiment of the present disclosure will be described with reference to FIG. 13.

As shown in FIG. 13, the voltage amplitude detection circuit 300 according to the third embodiment of the present disclosure includes a comparator 311, a flip-flop 312, a counter 313, and a frequency divider 314.

The comparator 311, like the comparator 111 shown in FIG. 4, compares the voltage amplitude of an input clock CLKIN with a predetermined reference voltage VREF. The comparator 311 compares the voltage amplitude of the input clock CLKIN with the predetermined reference voltage VREF, and outputs a predetermined signal COMPOUT at high level in the period in which the voltage amplitude of the input clock CLKIN is higher than the reference voltage VREF. In this embodiment, the signal COMPOUT output from the comparator 311 is sent to the frequency divider 314.

The frequency divider 314 generates signals DIVOUT and CLKFF having a phase difference of 90° from the signal COMPOUT output from the comparator 311. The signal DIVOUT is output to the flip-flop 312, and the signal CLKFF is output to the flip-flop 312 and the counter 313.

The flip-flop 312 captures the signal DIVOUT sent from the frequency divider 314 at a rising edge of the clock signal CLKFF. The flip-flop 312, by capturing the signal DIVOUT at a rising edge of the clock signal CLKFF, outputs a signal FFOUT at high level if the voltage amplitude of the input clock CLKIN is higher than the predetermined reference voltage VREF, and outputs a signal FFOUT at low level if the voltage amplitude of the input clock CLKIN is not higher than the predetermined reference voltage VREF. In this embodiment, the clock signal CLKFF is generated in the frequency divider 314.

The counter 313, like the counter 113 shown in FIG. 4, captures the signal FFOUT output from the flip-flop 312, and evaluates the content of the signal FFOUT on the basis of the clock signal CLKFF. Specifically, the counter 313, which operates by being supplied with the clock signal CLKF, starts a counting operation when the signal FFOUT has become high level and, after counting a predetermined number of times, outputs the evaluation result of the signal FFOUT as a signal DETOUT. The counter 313 can, by evaluating the content of the signal FFOUT on the basis of the clock signal CLKFF, more accurately determine if the voltage amplitude of the input clock CLKIN is higher than the predetermined reference voltage VREF. In this embodiment, the clock signal CLKFF is generated by the frequency divider 314.

Hereinabove, a specific exemplary circuit configuration of the voltage amplitude detection circuit 300 according to the third embodiment of the present disclosure has been described with reference to FIG. 13. Next, the operation of the voltage amplitude detection circuit 300 according to the third embodiment of the present disclosure will be described.

### [Operation of Voltage Amplitude Detection Circuit]

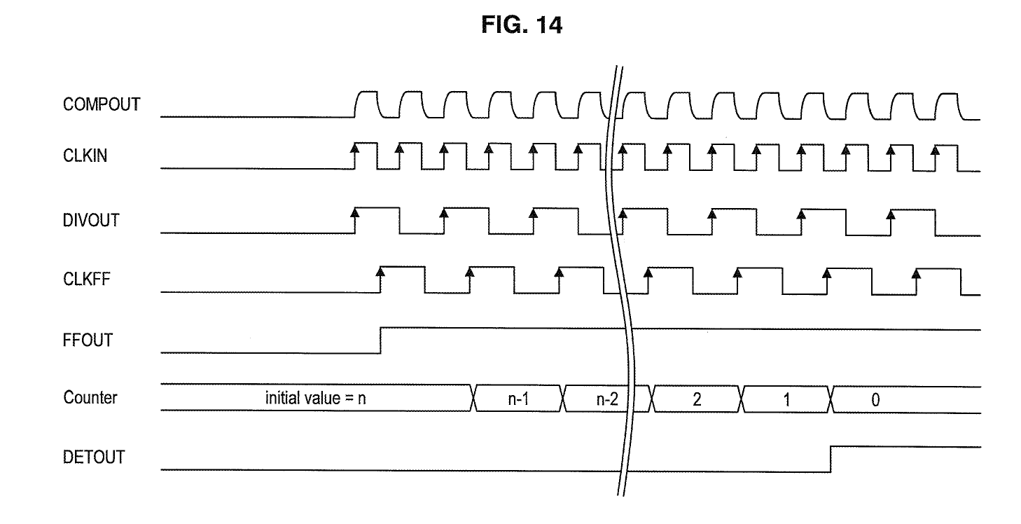

FIG. 14 is an illustration diagram showing a timing chart of a signal supplied to the voltage amplitude detection circuit 300 shown in FIG. 13. Hereinafter, the operation of the voltage amplitude detection circuit 300 according to the third embodiment of the present disclosure will be described with reference to FIG. 14.

Unless an input clock CLKIN is supplied to the voltage amplitude detection circuit 300, or even when an input clock CLKIN is supplied, if the voltage amplitude thereof is below a predetermined reference voltage VREF, the comparator 311 compares the voltage amplitude of the input clock CLKIN with the predetermined reference voltage VREF and, as the voltage amplitude of the reference voltage VREF is higher, outputs a signal COMPOUT at low level. As the signal COMPOUT is at low level, the signals DIVOUT and CLKFF output from the frequency divider 314 are also at low level.

As the signal CLKFF remains at low level, the flip-flop 312 does not output the content of the signal DIVOUT output from the frequency divider 314 and outputs a signal FFOUT at low level. The counter 313 has an initial value n, and operates by being supplied with the clock CLKFF. When the signal FFOUT is at high level at the timing of a rising edge of the clock CLKFF, the counter 313 counts down the count value, and when the signal FFOUT is at low level, the counter 313 resets the count value to the initial value. However, unless the input clock CLKIN is supplied to the voltage amplitude detection circuit 300 or when, even if the input clock CLKIN is supplied, the voltage amplitude thereof is below that of the predetermined reference voltage VREF, the signal CLKFF remains at low level. Thus, the counter 313 does not operate and the count value remains the initial value n.

When the voltage amplitude detection circuit 300 is supplied with an input clock CLKIN with a voltage amplitude higher than the reference voltage VREF, the comparator 111 compares the voltage amplitude of the input clock CLKIN with the predetermined reference voltage VREF and, as the voltage amplitude of the input clock CLKIN is higher, outputs a signal COMPOUT at high level in the period in which the voltage amplitude of the input clock CLKIN is higher. When the frequency divider 314 is supplied with the signal COMPOUT at high level in the period in which the voltage amplitude of the input clock CLKIN is higher, a signal DIVOUT with the same phase as the signal COMPOUT and a signal CLKFF with a phase relationship of 90° delayed from the signal DIVOUT are generated by the frequency divider 314.

The flip-flop 312, upon being supplied with the signal DIVOUT at high level, captures the signal DIVOUT at the timing of a rising edge of the signal CLKFF, and outputs a signal FFOUT at high level.

The counter 313, upon being supplied with the signal FFOUT at high level, counts down the count value at the timing of a rising edge of the signal CLKFF. Then, when the count value of the counter 313 has become zero, the counter 313 outputs a signal DETOUT at high level. When the signal DETOUT is at high level, it can be identified that an input clock CLKIN with a voltage amplitude higher than the reference voltage VREF has been supplied. Note that the counter 313 may be an up-counter. When the counter 313 is an up-counter, the counter 313 may output a signal DETOUT at high level at a point in time when the count value has reached a predetermined value.

When the voltage amplitude detection circuit 300 operates by being supplied with the input clock CLKIN as described above, even if the frequency of a clock to be detected is low, it is possible to detect generation of the clock without using a peak hold circuit that uses passive elements, like the voltage amplitude detection circuit 100 according to the first embodiment and the voltage amplitude detection circuit 200 according to the second embodiment.

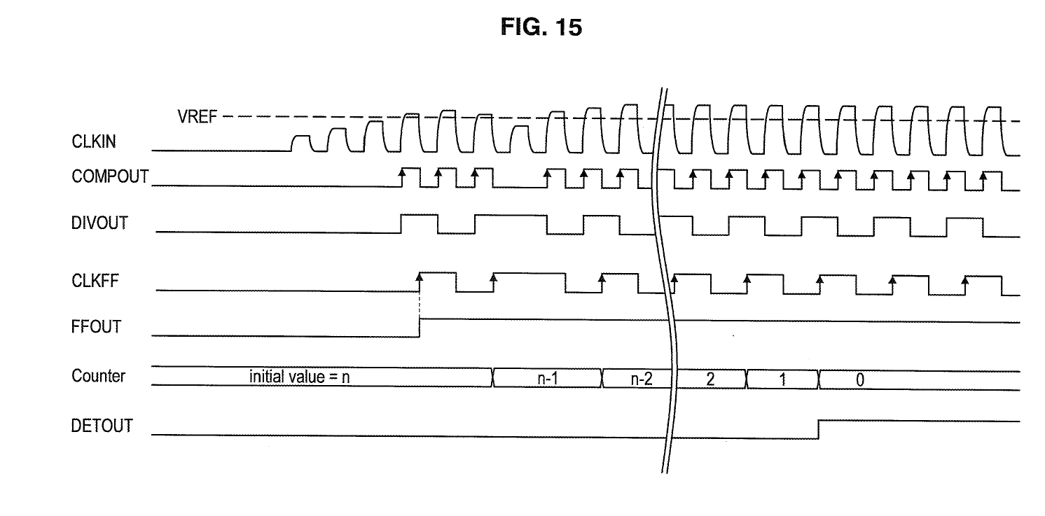

When an input clock CLKIN is stably supplied to the voltage amplitude detection circuit 300 as described above, the voltage amplitude of the clock is always higher than the reference voltage VREF. However, a case is considered in which, immediately after a clock is generated, a stable clock is not supplied to the voltage amplitude detection circuit 300. FIG. 15 is an illustration diagram showing a timing chart of a signal supplied to the voltage amplitude detection circuit 300 shown in FIG. 13, and shows a view in which the voltage amplitude of the input clock CLKIN is not stable.

As shown in FIG. 15, at the beginning of when an input clock CLKIN is supplied to the voltage amplitude detection circuit 300, if the voltage amplitude thereof is not higher than the reference voltage VREF, the count value of the counter 313 does not decrease. After that, when the voltage amplitude of the input clock CLKIN becomes higher than the reference voltage VREF, the count value of the counter 313 starts to decrease from n.

However, when the voltage amplitude of the input clock CLKIN becomes lower than the reference voltage VREF, the comparator 311 outputs a signal COMPOUT at low level. When the output of the signal COMPOUT becomes low level, the signal CLKFF generated from the signal COMPOUT also becomes low level. As the signal CLKFF becomes low level, the count value of the counter 313 is maintained (the count value remains n−1 in FIG. 15).

After that, when the voltage amplitude of the input clock CLKIN becomes higher than the reference voltage VREF again, the count value of the counter 313 starts to decrease from n−1, and when the count value of the counter 313 has become zero, the counter 313 outputs a signal DETOUT at high level. Accordingly, the count value of the counter 313 may be set to be a length that is long enough to wait until the input clock CLKIN is stabilized.

As the voltage amplitude detection circuit 300 uses a flip-flop without using passive elements, the voltage amplitude detection circuit 300 can be easily mounted on an integrated circuit. In addition, when the counter is operated for a given period of time using a held signal as a start signal and the output of the counter is used as a determination result, it is possible to eliminate detection errors by not outputting a detection result unless a stable clock is input. Further, when the voltage amplitude detection circuit 300 according to the third embodiment of the present disclosure generates a signal CLKFF to be supplied to the flip-flop 312 and the counter 313 from the output COMPOUT of the comparator 311 using the frequency divider 314, it becomes unnecessary to prepare a dedicated clock and achieve a further reduction in size of the voltage amplitude detection circuit 300 as compared to the voltage amplitude detection circuit 100 according to the first embodiment of the present disclosure. Furthermore, as the voltage amplitude detection circuit 300 according to the third embodiment of the present disclosure can accurately maintain a phase relationship of 90° between data and a clock input to the flip-flop 312 as compared to the voltage amplitude detection circuit 200 according to the second embodiment of the present disclosure, a more accurate detection operation can be performed.

### 5. Fourth Embodiment

### Exemplary Circuit Configuration of Voltage Amplitude Detection Circuit

In the descriptions heretofore, the voltage amplitude detection circuit according to each embodiment detects if the voltage amplitude of an input clock is higher than a single reference voltage. In a fourth embodiment of the present disclosure described below, a voltage amplitude detection circuit will be described in which two voltage detection systems for comparing the voltage amplitude of an input clock are provided and two reference voltages to be compared with the voltage amplitude of the input clock are provided.

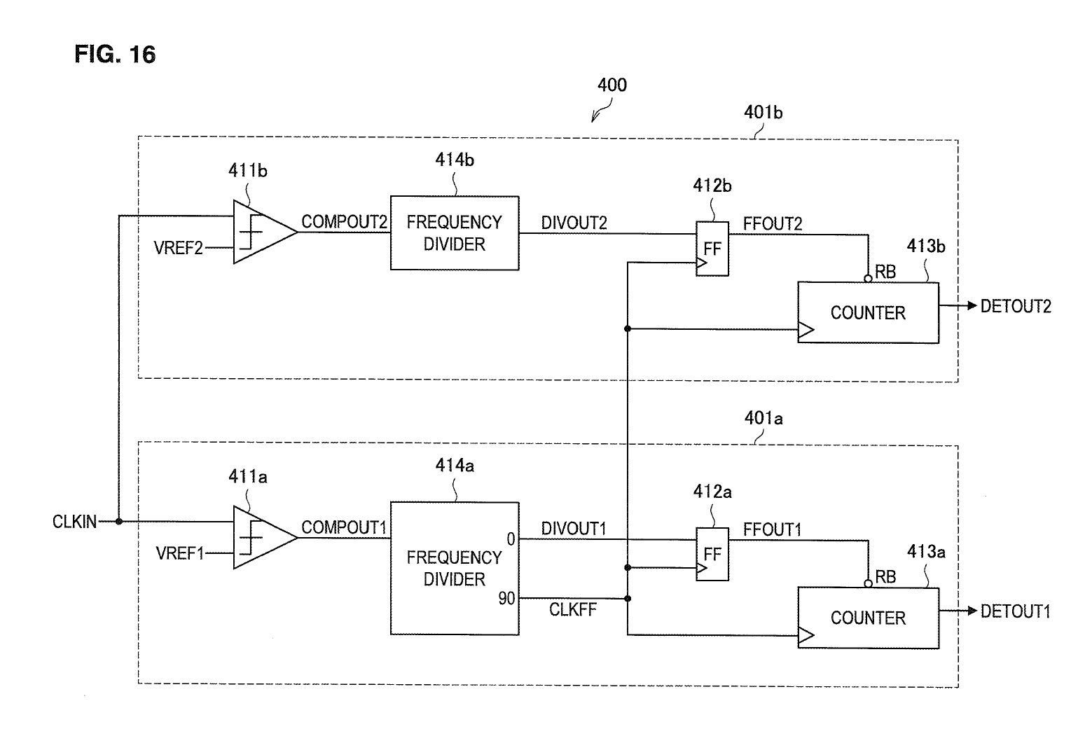

FIG. 16 is an illustration diagram showing a specific exemplary circuit configuration of a voltage amplitude detection circuit 400 according to the fourth embodiment of the present disclosure. Hereinafter, a specific exemplary circuit configuration of the voltage amplitude detection circuit 400 according to the fourth embodiment of the present disclosure will be described with reference to FIG. 16.

As shown in FIG. 16, the voltage amplitude detection circuit 400 according to the fourth embodiment of the present disclosure includes voltage detection units 401a and 401b. The voltage detection unit 401a includes a comparator 411a, a flip-flop 412a, a counter 413a, and a frequency divider 414a. The voltage detection unit 401b includes a comparator 411b, a flip-flop 412b, a counter 413b, and a frequency divider 414b.

The voltage detection units 401a and 401b detect if the voltage amplitude of an input clock CLKIN is higher than the voltage amplitudes of reference voltages VREF1 and VREF2, respectively. Note that VREF1<VREF2 herein.

The functions of the comparator 411a, the flip-flop 412a, the counter 413a, and the frequency divider 414a that constitute the voltage detection unit 401a are similar to the functions of the comparator 311, the flip-flop 312, the counter 313, and the frequency divider 314 according to the aforementioned third embodiment. Thus, detailed description thereof will be omitted. Likewise, the functions of the comparator 411b, the flip-flop 412b, the counter 413b, and the frequency divider 414b that constitute the voltage detection unit 401b are almost similar to the functions of the comparator 311, the flip-flop 312, the counter 313, and the frequency divider 314 according to the aforementioned third embodiment. Thus, detailed description thereof will be omitted. Note that the flip-flop 412b and the counter 413b operate by being supplied with the clock CLKFF generated by the frequency divider 414a of the voltage detection unit 401a.

Hereinabove, a specific exemplary circuit configuration of the voltage amplitude detection circuit 400 according to the fourth embodiment of the present disclosure has been described with reference to FIG. 16. Next, the operation of the voltage amplitude detection circuit 400 according to the fourth embodiment of the present disclosure will be described.

### [Operation of Voltage Amplitude Detection Circuit]

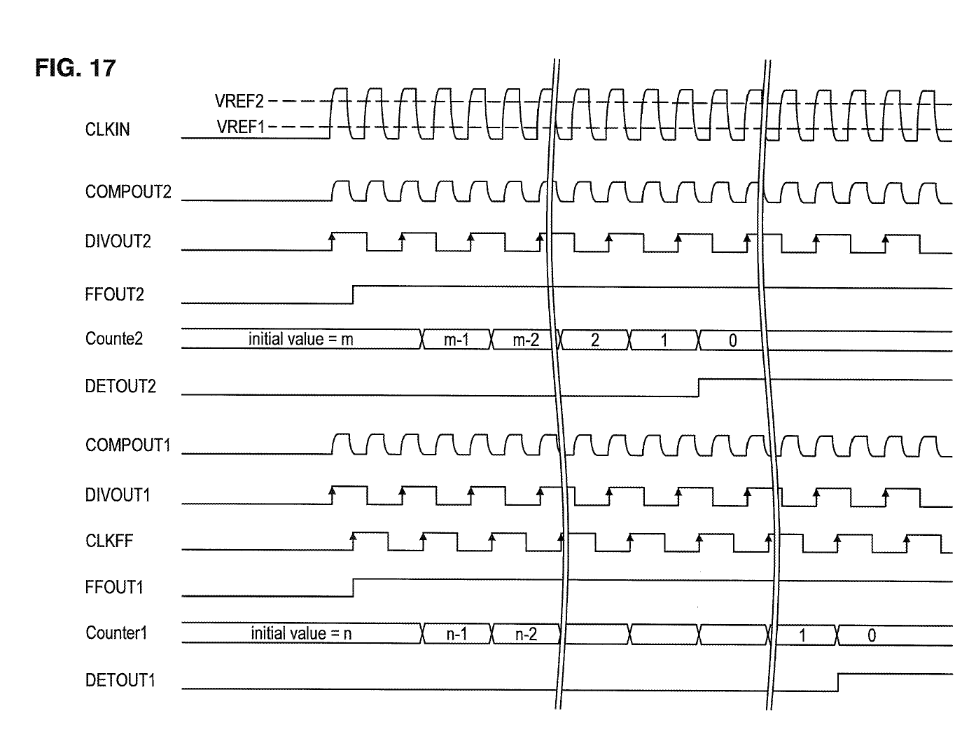

FIG. 17 is an illustration diagram showing a timing chart of a signal supplied to the voltage amplitude detection circuit 400 shown in FIG. 16. Hereinafter, the operation of the voltage amplitude detection circuit 400 according to the fourth embodiment of the present disclosure will be described with reference to FIG. 17.

Unless an input clock CLKIN is supplied to the voltage amplitude detection circuit 400, or even when an input clock CLKIN is supplied, if the voltage amplitude thereof is below the predetermined reference voltages VREF1 and VREF2, the comparators 411a and 411b compare the voltage amplitude of the input clock CLKIN with the voltage amplitudes of the predetermined reference voltages VREF1 and VREF2 and, as the voltage amplitudes of the reference voltages VREF1 and VREF2 are higher, output signals COMPOUT1 and COMPOUT 2 at low level, respectively. As the signals COMPOUT1 and COMPOUT2 are at low level, signals DIVOUT1 and DIVOUT2 output from the frequency dividers 414a and 414b, respectively and CLKFF are also at low level.

As the signal CLKFF remains at low level, the flip-flops 412a and 412b do not output the content of the signals DIVOUT output from the frequency dividers 414a and 414b, respectively, and output signals FFOUT1 and FFOUT2 at low level, respectively. The counters 413a and 413b each have an initial value n, and operate by being supplied with the clock CLKFF. If the signals FFOUT1 and FFOUT2 are at high level at the timing of a rising edge of the clock CLKFF, the counters 413a and 413b each count down the count value, and if the signals FFOUT1 and FFOUT 2 are at low level, the counters 413a and 413b each reset the count value to the initial value. However, unless the input clock CLKIN is supplied to the voltage amplitude detection circuit 400 or even when the input clock CLKIN is supplied, if the voltage amplitude thereof is below the voltage amplitudes of the predetermined reference voltages VREF1 and VREF2, the signal CLKFF remains at low level. Thus, the counters 413a and 413b do not operate and the count value remains the initial value n.

When the voltage amplitude detection circuit 400 is supplied with an input clock CLKIN with a voltage amplitude higher than the voltage amplitudes of the reference voltages VREF1 and VREF2, the comparators 411a and 411b compare the voltage amplitude of the input clock CLKIN with the voltage amplitudes of the predetermined reference voltages VREF1 and VREF2 and, as the voltage amplitude of the input clock CLKIN is higher, output signals COMPOUT1 and COMPOUT2 at high level in the period in which the voltage amplitude of the input clock CLKIN is higher, respectively. When the signals COMPOUT 1 and COMPOU2, which are at high level in the period in which the voltage amplitude of the input clock CLKIN is higher, are supplied to the frequency dividers 414a and 414b, respectively, a signal DIVOUT1 with the same phase as the signal COMPOUT1 and a signal CLKFF with a phase relationship of 90° delayed from the signal DIVOUT1 are generated by the frequency divider 414a, and a signal DIVOUT2 with the same phase as the signal COMPOUT 2 is generated by the frequency divider 414b.

When the flip-flops 412a and 412b are supplied with the signals DIVOUT1 and DIVOUT2 at high level, respectively, the flip-flops 412a and 412b capture the signals DIVOUT1 and DIVOUT2 at the timing of a rising edge of the signal CLKFF, and output signals FFOUT1 and FFOUT2 at high level.

The counters 413a and 413b, upon being supplied with the signals FFOUT1 and FFOUT2 at high level, respectively, count down the count values at the timing of a rising edge of the signal CLKFF. Then, when the count values of the counters 413a and 413b become zero, the counters 413a and 413b output signals DETOUT1 and DETOUT2 at high level, respectively. When the signals DETOUT1 and DETOUT 2 are at high level, it can be identified that an input clock CLKIN with a voltage amplitude higher than the voltage amplitudes of the reference voltages VREF1 and VREF2 has been supplied. Note that the counters 413a and 413b may be up-counters. When the counters 413a and 413b are up-counters, the counters 413a and 413b may output signals DETOUT1 and DETOUT2 at high level, respectively, at a point in time when the count values have reached a predetermined value.

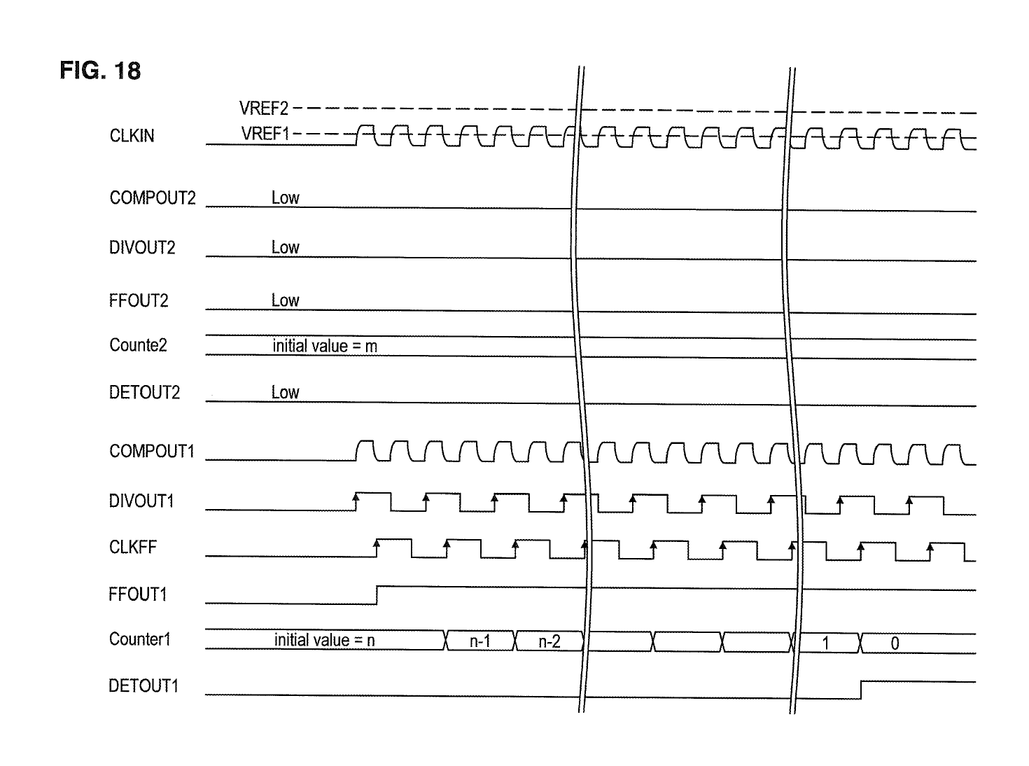

FIG. 18 is an illustration diagram showing a timing chart of a signal supplied to the voltage amplitude detection circuit 400 shown in FIG. 16. Hereinafter, the operation of the voltage amplitude detection circuit 400 according to the fourth embodiment of the present disclosure will be described with reference to FIG. 18.

When the voltage amplitude detection circuit 400 is supplied with an input clock CLKIN with a voltage amplitude that is higher than the voltage amplitude of the reference voltage VREF1 and is lower than the voltage amplitude of the reference voltage VREF2, the comparator 411a compares the voltage amplitude of the input clock CLKIN with the predetermined reference voltage VREF1 and, as the voltage amplitude of the input clock CLKIN is higher, outputs a signal COMPOUT 1 at high level in the period in which the voltage amplitude of the input clock CLKIN is higher. Meanwhile, the comparator 411b compares the voltage amplitude of the input clock CLKIN with the predetermined reference voltage VREF2 and, as the voltage amplitude of the reference voltage VREF2 is higher, outputs a signal COMPOUT at low level.

When the signal COMPOUT1, which is at high level in the period in which the voltage amplitude of the input clock CLKIN is higher than the reference voltage VREF1, is supplied to the frequency divider 414a, a signal DIVOUT1 with the same phase as the signal COMPOUT1 and a signal CLKFF with a phase relationship of 90° delayed from the signal DIVOUT1 are generated by the frequency divider 414a. Meanwhile, the signal DIVOUT2 at low level having the same phase as the signal COMPOUT2 at low level are generated by the frequency divider 414b.

The flip-flop 412a, upon being supplied with the signal DIVOUT1 at high level, captures the signal DIVOUT1 at the timing of a rising edge of the signal CLKFF, and outputs a signal FFOUT 1 at high level. Meanwhile, the flip-flop 412b, upon being supplied with the signal DIVOUT2 at low level, captures the signal DIVOUT2 at low level at the timing of a rising edge of the signal CLKFF, and outputs a signal FFOUT2 at low level.

The counter 413a, upon being supplied with the signal FFOUT1 at high level, counts down the count value at the timing of a rising edge of the signal CLKFF. Then, when the count value of the counter 413a has become zero, the counter 413a outputs a signal DETOUT1 at high level. Meanwhile, as the counter 413b is supplied with the signal FFOUT1 at low level, the count value remains the initial value n. When only the signal DETOUT1 is at high level, it can be identified that an input clock CLKIN with a voltage amplitude that is higher than the voltage amplitude of the reference voltage VREF1 and is lower than the voltage amplitude of reference voltage VREF2 has been supplied. Note that the counters 413a and 413b may be up-counters. When the counters 413a and 413b are up-counters, the counters 413a and 413b may output the signals DETOUT1 and DETOUT2 at high level at a point in time when the count values have reached a predetermined value.

When the voltage amplitude detection circuit 400 operates by being supplied with the input clock CLKIN as described above, even if the frequency of a clock to be detected is low, it is possible to detect generation of the clock without using a peak hold circuit that uses passive elements, like the voltage amplitude detection circuit 100 according to the first embodiment, the voltage amplitude detection circuit 200 according to the second embodiment, and the voltage amplitude detection circuit 300 according to the third embodiment.

As the voltage amplitude detection circuit 400 uses a flip-flop without using passive elements, the voltage amplitude detection circuit 400 can be easily mounted on an integrated circuit. In addition, when the counter is operated for a given period of time using a held signal as a start signal and the output of the counter is used as a determination result, it is possible to eliminate detection errors by not outputting a detection result unless a stable clock is input. Further, when the voltage amplitude detection circuit 400 according to the fourth embodiment of the present disclosure generates a signal CLKFF to be supplied to the flip-flops 412a and 412b and the counters 413a and 413b from the output COMPOUT1 of the comparator 411a using the frequency divider 414a, it becomes unnecessary to prepare a dedicated clock and achieve a further reduction in size of the voltage amplitude detection circuit 400 as compared to the voltage amplitude detection circuit 100 according to the first embodiment.

Further, when the voltage amplitude detection circuit 400 is provided with two voltage detection systems for comparing the voltage amplitude of the input clock, and two reference voltages to be compared with the voltage amplitude of the input clock are set, it becomes possible to detect the voltage amplitude of the input clock more specifically.

The voltage amplitude detection circuit 400 according to this embodiment can be applied to SDIO 3.0, for example. SDIO 3.0 includes a specification in which the signal level is switched between 3.3 V and 1.8 V according to an operation mode. A card device that adopts SDIO 3.0 is required to have a function of detecting a clock amplitude. The frequency at which the clock amplitude is detected is set low like 100 kHz to 400 kHz. Thus, with a method that uses an analog peak hold circuit such as the one shown in the prior art, the peak hold circuit necessarily occupies quite a large area.

In this embodiment, the first reference voltage VREF1 is set lower than 1.8 V, and the second reference voltage VREF2 is set between 1.8 V and 3.3 V, whereby it becomes possible to distinguish between three states: a state in which a clock does not exist, a state in which the clock amplitude is between 1.8 V to 3.3 V, and a state in which the clock amplitude is 3.3 V.

### 6. Fifth Embodiment

### Exemplary Circuit Configuration of Voltage Amplitude Detection Circuit

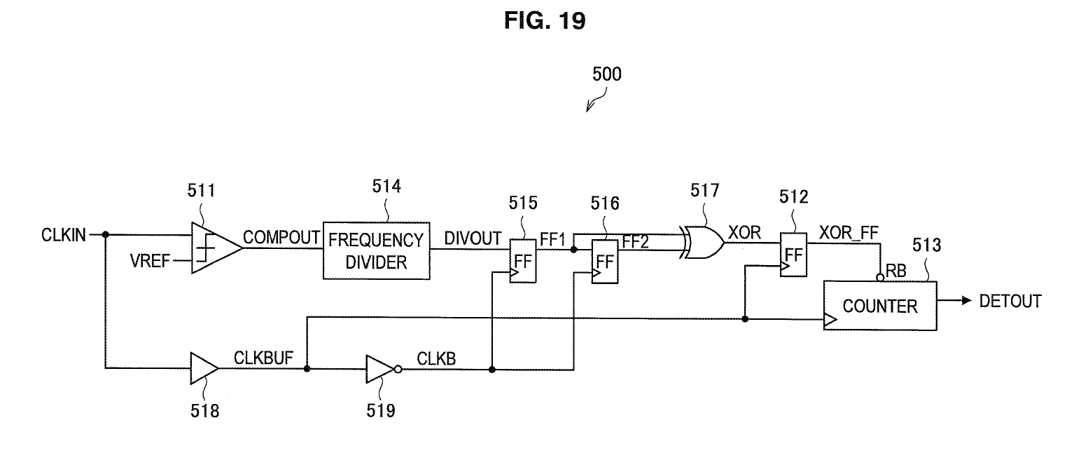

In a fifth embodiment of the present disclosure described below, a configuration in which the voltage amplitude of an input clock is detected without using a delay circuit used in the aforementioned embodiments will be described. FIG. 19 is an illustration diagram showing the configuration of a voltage amplitude detection circuit 500 according to the fifth embodiment of the present disclosure. Hereinafter, the configuration of the voltage amplitude detection circuit 500 according to the fifth embodiment of the present disclosure will be described with reference to FIG. 19.

As shown in FIG. 19, the voltage amplitude detection circuit 500 according to the fifth embodiment of the present disclosure includes a comparator 511, flip-flops 512, 515, and 516, a counter 513, a frequency divider 514, an exclusive OR 517, a clock buffer 518, and an inverter 519.

As the functions of the comparator 511, the counter 513, and the frequency divider 514 are similar to the functions of the comparator 311, the flip-flop 312, the counter 313, and the frequency divider 314 according to the aforementioned third embodiment, detailed description thereof will be omitted. The flip-flop 515 is driven by an inverted clock signal CLKB output from the inverter 519, captures an output DIVOUT of the frequency divider 514, and supplies an output signal FF1 to the flip-flop 516 and the exclusive OR 517. The flip-flop 516 is driven by an inverted clock signal CLKB output from the inverter 519, captures the output signal FF1 of the flip-flop 515, and supplies an output signal FF2 to the exclusive OR 517. The exclusive OR 517 determines exclusive OR of the output signal FF1 of the flip-flop 515 and the output signal FF2 of the flip-flop 516, and supplies the output signal XOR to the flip-flop 512. The flip-flop 512 is driven by an output signal CLKBUF of the clock buffer 518, captures the output signal XOR of the exclusive OR 517, and supplies the output signal XOR_FF to the counter 513.

The clock buffer 518 amplifies the input clock signal CLKIN by a predetermined amount, and outputs an output signal CLKBUF. The inverter 519 inverts the output signal CLKBUF of the clock buffer 518 and outputs an output signal CLKB.

Hereinabove, a specific exemplary circuit configuration of the voltage amplitude detection circuit 500 according to the fifth embodiment of the present disclosure has been described with reference to FIG. 19. Next, the operation of the voltage amplitude detection circuit 500 according to the fifth embodiment of the present disclosure will be described.

### [Operation of Voltage Amplitude Detection Circuit]

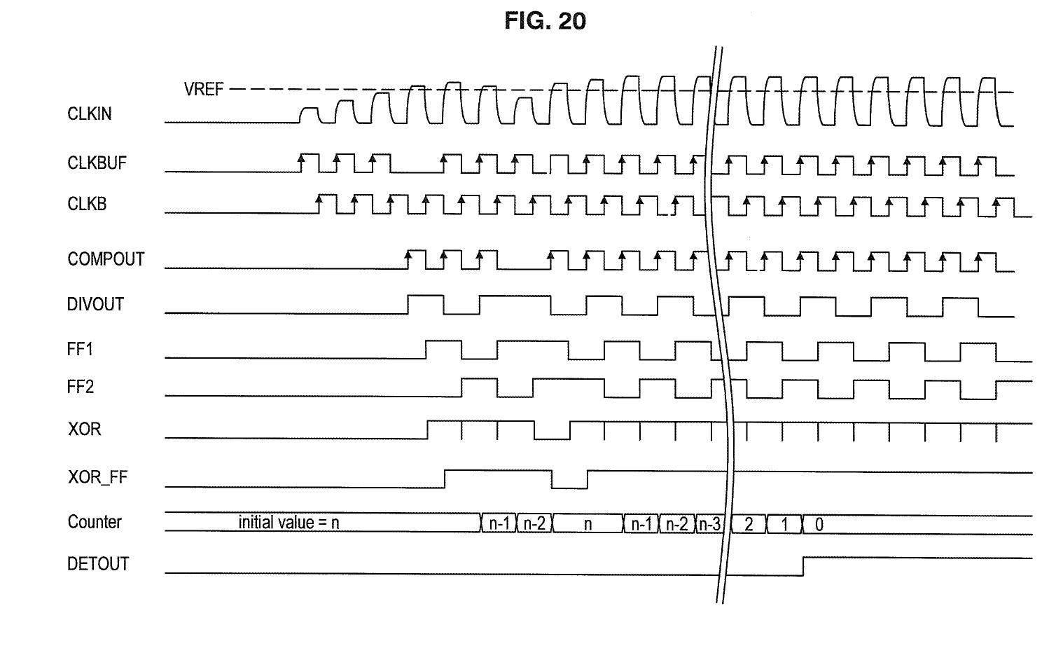

FIG. 20 is an illustration diagram showing a timing chart of a signal supplied to the voltage amplitude detection circuit 500 shown in FIG. 19. Hereinafter, the operation of the voltage amplitude detection circuit 500 according to the fifth embodiment of the present disclosure will be described with reference to FIG. 20.

Unless an input clock CLKIN is supplied to the voltage amplitude detection circuit 500, or even when an input clock CLKIN is supplied, if the voltage amplitude thereof is below that of a predetermined reference voltage VREF, the comparator 511 compares the voltage amplitude of the input clock CLKN with the predetermined reference voltage VREF and, as the voltage amplitude of the reference voltage VREF is higher, outputs a signal COMPOUT at low level. As the signal COMPOUT is at low level, the signal DIVOUT output from the frequency divider 514, the output signal FF1 output from the flip-flop 515, the output signal FF2 output from the flip-flop 516, the output signal XOR output from the exclusive OR 517, and the output signal XOR_FF output from the flip-flop 512 are also at low level.

The counter 513 has an initial value n, and operates by being supplied with the clock CLKBUF. If the signal XOR_FF is at high level at the timing of a rising edge of the clock CLKBUF, the counter 513 counts down the count value, and if the signal XOR_FF is at low level, the counter 513 resets the count value to the initial value. However, unless an input clock CLKIN is supplied to the voltage amplitude detection circuit 500, or even when an input clock CLKIN is supplied, if the voltage amplitude thereof is below that of the predetermined reference voltage VREF, the signal XOR_FF remains at low level. Thus, the counter 513 does not operate, and the count value remains the initial value n.

Note that when the input clock CLKIN is supplied, the output signal CLKBUF output from the clock buffer 518 and the output signal CLKB output from the inverter 519 switch between high level and low level in synchronization with the clock or at the timing of a half cycle delayed from the clock.

When the voltage amplitude detection circuit 500 is supplied with an input clock CLKIN with a voltage amplitude higher than the reference voltage VREF, the comparator 511 compares the voltage amplitude of the input clock CLKIN with the predetermined reference voltage VREF and, as the voltage amplitude of the input clock CLKIN is higher, outputs a signal COMPOUT at high level in the period in which the voltage amplitude of the input clock CLKIN is higher. When the signal COMPOUT, which is at high level in the period in which the voltage amplitude of the input clock CLKIN is higher, is supplied to the frequency divider 514, a signal DIVOUT with the same phase as the signal COMPOUT is generated by the frequency divider 514.

The flip-flops 515 and 516 are driven by the inverted clock CLKB. Thus, the flip-flops 515 and 516 can capture a moment at which the output of the output signal DIVOUT output from the frequency divider is stabilized. When the input signal CLKIN has reached a predetermined amplitude, the frequency divider 514 operates stably. Thus, the output signal DIVOUT of the frequency divider 514 toggles between high level and low level in periods of the input signal CLKIN. Thus, when the output signal DIVOUT toggles between high level and low level in periods of the input signal CLKIN, the polarity of the output signal FF1 of the flip-flip 515 and the polarity of the output signal FF2 of the flip-flop 516 are inverted. Thus, the exclusive OR 517 outputs a signal at high level.

Meanwhile, when the input signal CLKIN becomes lower than the predetermined amplitude, the comparator 511 does not output an output signal COMPOUT at high level, and thus the operation of the frequency divider 514 stops. In such a case, the polarity of the output signal FF1 of the flip-flop 515 coincides with the polarity of the output signal FF2 of the flip-flop 516, and the exclusive OR 517 outputs a signal at low level. When the exclusive OR 517 outputs a signal at low level, the flip-flop 512 also outputs an output signal XOR_FF at low level. Thus, the count value of the counter 513 is reset.

The exclusive OR 517 outputs a glitch upon change of an input signal. When the flip-flop 512 driven by the signal CLKBUF captures the output signal XOR of the exclusive OR 517, the glitch is removed. When the output signal XOR_FF of the flip-flop 512 is set high, reset of the counter 513 is cancelled, and the counting operation is resumed. That is, if the input signal CLKIN is stably input, the counter 513 outputs a detection result DETOUT after counting a predetermined number of times. Note that the counter 513 may be an up-counter. When the counter 513 is an up-counter, the counter 513 may output a signal DETOUT at high level at a point in time when the count value has reached a predetermined value.

As the voltage amplitude detection circuit 500 according to the fifth embodiment of the present disclosure uses a flip-flop without using passive elements, the voltage amplitude detection circuit 500 can be easily mounted on an integrated circuit. In addition, when the counter is operated for a given period of time using a held signal as a start signal and the output of the counter is used as a determination result, it is possible to eliminate detection errors by not outputting a detection result unless a stable clock is input. Further, the voltage amplitude detection circuit 500 according to the fifth embodiment of the present disclosure can determine a phase relationship in association with the clock period of an input signal without using a delay circuit used in the aforementioned embodiments and can, if the voltage amplitude of the input signal is not stable, immediately reset the counter.

### 7. Sixth Embodiment

### Exemplary Circuit Configuration of Voltage Amplitude Detection Circuit

The voltage amplitude detection circuit 500 according to the fifth embodiment of the present disclosure detects if the voltage amplitude of the input clock is higher than a single reference voltage. In a sixth embodiment of the present disclosure described below, a voltage amplitude detection circuit will be described in which two voltage detection systems for comparing the voltage amplitude of an input clock are provided and two reference voltages to be compared with the voltage amplitude of the input clock are set as in the aforementioned fourth embodiment of the present disclosure.

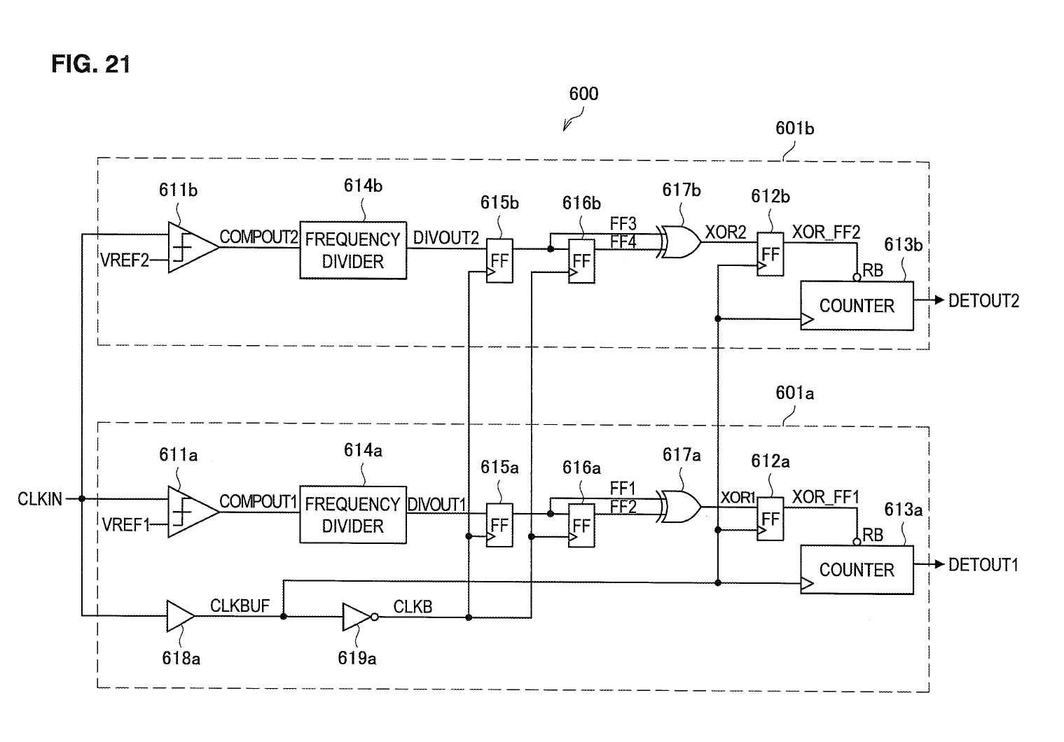

FIG. 21 is an illustration diagram showing a specific exemplary circuit configuration of a voltage amplitude detection circuit 600 according to the sixth embodiment of the present disclosure. Hereinafter, a specific exemplary circuit configuration of the voltage amplitude detection circuit 600 according to the sixth embodiment of the present disclosure will be described with reference to FIG. 21.

As shown in FIG. 21, the voltage amplitude detection circuit 600 according to the sixth embodiment of the present embodiment includes voltage detection units 601a and 601b. The voltage detection unit 601a includes a comparator 611a, flip-flops 612a, 615a, and 616a, a counter 613a, a frequency divider 614a, an exclusive OR 617a, a clock buffer 618a, and an inverter 619a. The voltage detection unit 601b includes a comparator 611b, flip-flops 612b, 615b, and 616b, a counter 613b, a frequency divider 614b, and an exclusive OR 617b.

The voltage detection units 601a and 601b detect if the voltage amplitude of the input clock CLKIN is higher than the voltage amplitudes of reference voltages VREF1 and VREF2, respectively. Note that VREF1<VREF2.

As the functions of the comparator 611a, the flip-flops 612a, 615a, and 616a, the counter 613a, the frequency divider 613a, the exclusive OR 617a, the clock buffer 618a, and the inverter 619a that constitute the voltage detection unit 601a are similar to the functions of the comparator 511, the flip-flops 512, 515, and 516, the counter 513, the frequency divider 514, the exclusive OR 517, the clock buffer 518, and the inverter 519 according to the aforementioned fifth embodiment, detailed description thereof will be omitted. Likewise, as the functions of the comparator 611b, the flip-flops 612b, 615b, 616b, the counter 613b, the frequency divider 614b, and the exclusive OR 617b that constitute the voltage detection unit 601b are substantially similar to the functions of the comparator 511, the flip-flops 512, 515, and 516, the counter 513, the frequency divider 514, and the exclusive OR 517 according to the aforementioned fifth embodiment, detailed description thereof will be omitted. Note that the flip-flop 612b and the counter 613b operate by being supplied with a signal CLKBUF generated by the clock buffer 618a of the voltage detection unit 401a. In addition, the flip-flops 615b and 616b operate by being supplied with a signal CLKB generated by the inverter 619a of the voltage detection unit 401a.

Hereinabove, a specific exemplary circuit configuration of the voltage amplitude detection circuit 600 according to the sixth embodiment of the present disclosure has been described with reference to FIG. 21. Next, the operation of the voltage amplitude detection circuit 600 according to the sixth embodiment of the present disclosure will be described.

### [Operation of Voltage Amplitude Detection Circuit]

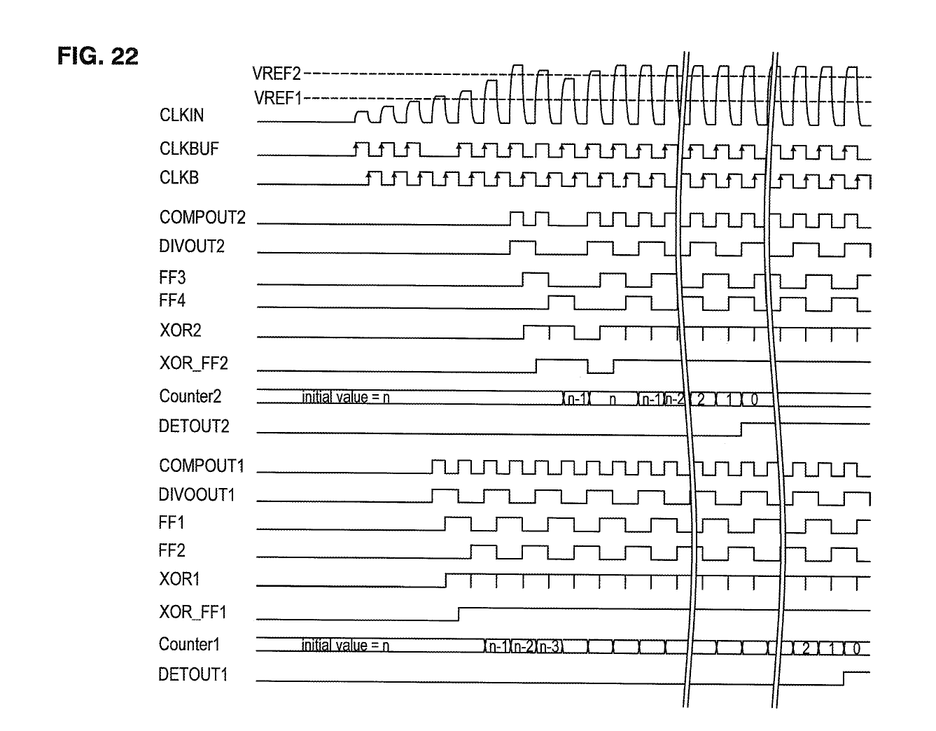

FIG. 22 is an illustration diagram showing a timing chart of a signal supplied to the voltage amplitude detection circuit 600 shown in FIG. 21. Hereinafter, the operation of the voltage amplitude detection circuit 600 according to the sixth embodiment of the present disclosure will be described with reference to FIG. 22.

Unless an input clock CLKIN is supplied to the voltage amplitude detection circuit 600, or even when an input clock CLKIN is supplied, if the voltage amplitude thereof is below the voltage amplitudes of predetermined reference voltages VREF1 and VREF2, the comparators 611a and 611b compare the voltage amplitude of the input clock CLKIN with the voltage amplitudes of the predetermined reference voltages VREF1 and VREF2, respectively and, as the voltage amplitudes of the reference voltages VREF1 and VREF2 are higher, output signals COMPOUT1 and COMPOUT2 at low level, respectively. As the signals COMPOUT1 and COMPOUT2 are at low level, the signals DIVOUT1 and DIVOUT2 output from the frequency dividers 614a and 614b, respectively are also at low level. Further, the output signal FF1 output from the flip-flop 615a, the output signal FF2 output from the flip-flop 616a, the output signal XOR1 output from the exclusive OR 617a, and the output signal XOR_FF1 output from the flip-flop 612a are also at low level. Further, the output signal FF3 output from the flip-flop 615b, the output signal FF4 output from the flip-flop 616b, the output signal XOR2 output from the exclusive OR 617b, and the output signal XOR_FF2 output from the flip-flop 612b are also at low level.

The counters 613a and 613b each have an initial value n, and operate by being supplied with the clock CLKBUF. If the signals XOR_FF1 and XOR_FF2 are at high level at the timing of a rising edge of the clock CLKBUF, the counters 613a and 613b count down the count value, and if the signals XOR_FF1 and XOR_FF2 are at low level, the counters 613a and 613b reset the count value to the initial value. However, unless the input clock CLKIN is supplied to the voltage amplitude detection circuit 600 or even when the input clock CLKIN is supplied, if the voltage amplitude thereof is below the voltage amplitudes of the predetermined reference voltages VREF1 and VREF2, the signals XOR_FF1 and XOR_FF2 remain at low level. Thus, the counters 613a and 613b do not operate and the count value remains the initial value n.

Note that when the input clock CLKIN is supplied, the output signal CLKBUF output from the clock buffer 618a and the output signal CLKB output from the inverter 619a switch between high level and low level in synchronization with the clock or at the timing of a half cycle delayed from the clock.

When the voltage amplitude detection circuit 600 is supplied with an input clock CLKIN with a voltage amplitude higher than the reference voltage VREF1, the comparator 611a compares the voltage amplitude of the input clock CLKIN with the predetermined reference voltage VREF1 and, as the voltage amplitude of the input clock CLKIN is higher, outputs a signal COMPOUT1 at high level in the period in which the voltage amplitude of the input clock CLKIN is higher. When the signal COMPOUT1, which is at high level in the period in which the voltage amplitude of the input clock CLKIN is higher, is supplied to the frequency divider 614a, a signal DIVOUT1 with the same phase as the signal COMPOUT1 is generated by the frequency divider 614a. Note that unless the voltage amplitude of the input clock CLKIN is higher than the reference voltage VREF2, the signal COMPOUT2 output from the comparator 611b remains at low level.

After that, when the voltage amplitude detection circuit 600 is supplied with an input clock CLKIN with a voltage amplitude higher than the reference voltage VREF2, the comparator 611b compares the voltage amplitude of the input clock CLKIN with the predetermined reference voltage VREF2 and, as the voltage amplitude of the input clock CLKIN is higher, outputs a signal COMPOUT2 at high level in the period in which the voltage amplitude of the input clock CLKIN is higher. When the signal COMPOUT2, which is at high level in the period in which the voltage amplitude of the input clock CLKIN is higher, is supplied to the frequency divider 614b, a signal DIVOUT2 with the same phase as the signal COMPOUT2 is generated by the frequency divider 614b.

As the flip-flops 615a and 616a are driven by the inverted clock CLKB, the flip-flops 615a and 616a can capture moments at which the outputs of the output signals DIVOUT1 and DIVOUT2 output from the frequency dividers are stable, respectively. When the input signal CLKIN has reached a predetermined amplitude, the frequency divider 614a operates stably. Thus, the output signal DIVOUT1 of the frequency divider 614a toggles between high level and low level in periods of the input signal CLKIN. Thus, when the output signal DIVOUT1 toggles between high level and low level in periods of the input signal CLKIN, the polarity of the output signal FF1 of the flip-flip 615a and the polarity of the output signal FF2 of the flip-flop 616a are inverted. Thus, the exclusive OR 617a outputs a signal at high level. Likewise, when the output signal DIVOUT2 toggles between high level and low level in periods of the input signal CLKIN, the polarity of the output signal FF3 of the flip-flip 615a and the polarity of the output signal FF4 of the flip-flop 616b are inverted. Thus, the exclusive OR 617b outputs a signal at high level.

Meanwhile, when the input signal CLKIN becomes lower than the predetermined amplitude, the comparators 611a and 611b do not output the output signals COMPOUT1 and COMPOUT2 at high level, respectively, and the operations of the frequency dividers 614a and 614b stop. In this case, as the polarity of the output signal FF1 of the flip-flop 615a coincides with the polarity of the output signal FF2 of the flip-flop 616a, the exclusive OR 617a outputs a signal at low level. In addition, as the polarity of the output signal FF3 of the flip-flop 615b coincides with the polarity of the output signal FF4 of the flip-flop 616b, the exclusive OR 617b outputs a signal at low level. When the exclusive OR 617a outputs a signal at low level, the flip-flop 612a also outputs an output signal XOR_FF1 at low level, and the count value of the counter 613a is reset. Likewise, when the exclusive OR 617b outputs a signal at low level, the flip-flop 612b also outputs an output signal XOR_FF2 at low level, and the count value of the counter 613b is reset.

The exclusive ORs 617a and 617b output a glitch upon change of an input signal. When the flip-flops 612a and 612b driven by the signal CLKBUF capture the output the signals XOR1 and XOR2 of the exclusive ORs 617a and 617b, respectively, the glitch is removed. When the output signal XOR_FF1 of the flip-flop 612a is set high, reset of the counter 613a is cancelled, and the counting operation is resumed. Likewise, when the output signal XOR_FF2 of the flip-flop 612b is set high, reset of the counter 613b is cancelled, and the counting operation is resumed. That is, when an input signal CLKIN is stably input, the counters 613a and 613b output detection results DETOUT1 and DETOUT2, respectively, after counting a predetermined number of times. Note that the counters 613a and 613b may be up-counters. When the counters 613a and 613b are up-counters, the counters 613a and 613b may each output a signal DETOUT at high level at a point in time when the count value has reached a predetermined value.

As the voltage amplitude detection circuit 600 according to the sixth embodiment of the present disclosure uses a flip-flop without using passive elements, the voltage amplitude detection circuit 600 can be easily mounted on an integrated circuit. In addition, when the counter is operated for a given period of time using a held signal as a start signal and the output of the counter is used as a determination result, it is possible to eliminate detection errors by not outputting a detection result unless a stable clock is input. Further, the voltage amplitude detection circuit 600 according to the sixth embodiment of the present disclosure can determine a phase relationship in association with a clock period of an input signal without using a delay circuit used in the aforementioned embodiments and can, if the voltage amplitude of the input signal is not stable, immediately reset the counter.

In the voltage amplitude detection circuit 600 according to the sixth embodiment of the present disclosure, two voltage detection systems for comparing the voltage amplitude of the input clock are provided, and two reference voltages for comparing the voltage amplitude of the input clock are set, whereby the voltage amplitude of the input clock can be detected more specifically.

### 8. Examples of Application of Voltage Amplitude Detection Circuit

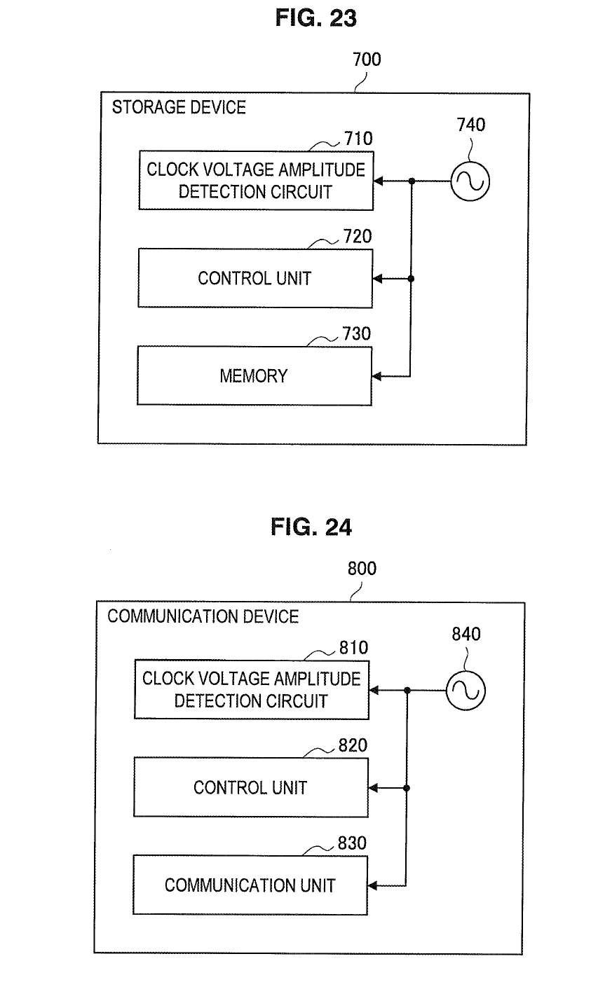

Next, examples of the application of the voltage amplitude detection circuit according to each of the aforementioned embodiments will be described. FIG. 23 is an illustration diagram showing the functional configuration of a storage device 700 having the voltage amplitude detection circuit according to each of the aforementioned embodiments.

The storage device 700 having the voltage amplitude detection circuit according to each of the aforementioned embodiments includes a voltage amplitude detection circuit 710 corresponding to a voltage amplitude detection circuit according to any one of the aforementioned embodiments, a control unit 720 that controls the storage device 700, memory 730 that stores data, and an oscillator 740 that generates a clock. The voltage amplitude detection circuit 710 detects the amplitude of a clock output from the oscillator 740, and transmits the detection result to the control unit 720. The control unit 720 controls the memory 730 on the basis of the detection result.

Although a configuration in which the storage device 700 has the oscillator 740 has been described as an example, it is also possible to use a configuration in which an external oscillator supplies a clock to the storage device 700.

FIG. 24 is an illustration diagram showing the functional configuration of a communication device 800 having the voltage amplitude detection circuit according to each of the aforementioned embodiments.

The communication device 800 having the voltage amplitude detection circuit according to each of the aforementioned embodiments includes a voltage amplitude detection circuit 810 corresponding to a voltage amplitude detection circuit according to any one of the aforementioned embodiments, a control unit 820 that controls the communication device 800, a communication unit 830 that communicates with an external device using a predetermined communication scheme, and an oscillator 840 that generates a clock. The voltage amplitude detection circuit 810 detects the amplitude of a clock output from the oscillator 840, and transmits the detection result to the control unit 820. The control unit 820 communicates with an external device. The communication scheme of the communication unit 830 is not particularly limited and may be either wire communication or wireless communication.

Although a configuration in which the communication device 800 has the oscillator 840 has been described as an example, it is also possible to use a configuration in which an external oscillator supplies clocks to the communication device 800.

As described above, when the storage device 700 or the communication device 800 has a voltage amplitude detection circuit according to any one of the aforementioned embodiments, it is possible to detect the voltage amplitude of a clock and control the operation of the storage device 700 or the communication device 800 on the basis of the detection result.

### 9. CONCLUSION

As described above, according to each of the aforementioned embodiments of the present disclosure, as a flip-flop is used without using passive elements, it is possible to provide a voltage amplitude detection circuit that can be easily mounted on an integrated circuit. In addition, according to the voltage amplitude detection circuit according to each embodiment of the present disclosure, when a counter is operated for a given period of time using a held signal as a start signal and the output of the counter is used as a determination result, it is possible to eliminate detection errors by not outputting a detection result unless a stable clock is input.

In addition, according to a voltage amplitude detection circuit according to an embodiment of the present disclosure, when a signal to be supplied to a flip-flop and a counter is generated from an output of a comparator, it is possible to achieve a reduction in size without the need to prepare a dedicated clock.

Further, according to a voltage amplitude detection circuit according to an embodiment of the present disclosure, when two voltage detection systems for comparing the voltage amplitude of an input clock are provided and two reference voltages for comparing the voltage amplitude of the input clock are set, it is possible to detect the voltage amplitude of an input clock more specifically. Furthermore, according to the voltage amplitude detection circuit according to an embodiment of the present disclosure, it is possible to determine the positional relationship in association with a clock period of an input clock and, if the voltage amplitude of the input signal is not stable, immediately reset the counter.

Although the preferred embodiments of the present disclosure have been described in detail with reference to the appended drawings, the present disclosure is not limited thereto. It is obvious to those skilled in the art that various modifications or variations are possible insofar as they are within the technical scope of the appended claims or the equivalents thereof. It should be understood that such modifications or variations are also within the technical scope of the present disclosure.

Additionally, the present technology may also be configured as below. Additionally, the present technology may also be configured as below.

(1) A voltage amplitude detection circuit including:

a first comparison unit configured to compare a voltage amplitude of an input signal with a predetermined voltage and output a comparison result;

a first comparison result holding unit configured to hold the comparison result output from the first comparison unit in predetermined periods of a driving clock, and output the held comparison result; and

a first comparison result evaluation unit configured to evaluate the comparison result output from the first comparison result holding unit in the predetermined periods of the driving clock and output an evaluation result.

(2) The voltage amplitude detection circuit according to (1), further including a delay unit configured to delay the output of the first comparison unit by a predetermined time, and output the delayed output to the first comparison result holding unit and the first comparison result evaluation unit.
(3) The voltage amplitude detection circuit according to (1) or (2), further including a delay unit configured to delay the input signal by a predetermined time, and output the delayed input signal to the first comparison result holding unit and the first comparison result evaluation unit.
(4) The voltage amplitude detection circuit according to any one of (1) to (3), further including a first frequency dividing unit configured to output the output of the first comparison unit to the first comparison result holding unit and also divide a frequency of the output of the first comparison unit and output the frequency-divided output to the first comparison result holding unit and the first comparison result evaluation unit.
(5) The voltage amplitude detection circuit according to (4), further including:

a second comparison unit configured to compare the voltage amplitude of the input signal with a second predetermined voltage that is higher than the first predetermined voltage and output a comparison result;

a second comparison result holding unit configured to hold the comparison result output from the second comparison unit in predetermined periods of a driving clock and output the held comparison result; and

a second comparison result evaluation unit configured to evaluate the comparison result output from the second comparison result holding unit in the predetermined periods of the driving clock and output an evaluation result,

wherein the first frequency dividing unit divides the frequency of the output of the first comparison unit and output the frequency-divided output to the first comparison result holding unit, the first comparison result evaluation unit, and the second comparison result holding unit.

(6) The voltage amplitude detection circuit according to (4) or (5), further including:

a first flip-flop configured to capture an output signal of the first frequency-dividing unit by being driven at a falling edge of the clock;

a second flip-flop configured to capture an output of the first flip-flop; and

a first output evaluation unit configured to evaluate output signals of the first flip-flop and the second flip-flop.

(7) The voltage amplitude detection circuit according to (6), wherein the first output evaluation unit performs evaluation by calculating exclusive OR of the output signals of the first flip-flop and the second flip-flop.
(8) The voltage amplitude detection circuit according to (6) or (7), further including a first noise removing unit configured to remove noise of an output of the first output evaluation unit.
(9) The voltage amplitude detection circuit according to any one of (6) to (8), further including:

a second comparison unit configured to compare the voltage amplitude of the input signal with a second predetermined voltage that is higher than the first predetermined voltage, and output a comparison result;

a second comparison result holding unit configured to hold the comparison result output from the second comparison unit in predetermined periods of a driving clock, and output the held comparison result;

a second comparison result evaluation unit configured to evaluate the comparison result output from the second comparison result holding unit in the predetermined periods of the driving clock, and output an evaluation result;

a third flip-flop configured to capture an output signal of the second comparison unit by being driven at a falling edge of the clock;

a fourth flip-flop configured to capture an output of the third flip-flop; and

a second output evaluation unit configured to evaluate output signals of the third flip-flop and the fourth flip-flop.

(10) The voltage amplitude detection circuit according to any one of (6) to (9), wherein the second output evaluation unit performs evaluation by calculating exclusive OR of the output signals of the third flip-flop and the fourth flip-flop.
(11) The voltage amplitude detection circuit according to any one of (6) to (10), further including a second noise removing unit configured to remove noise of an output of the second output evaluation unit.
(12) An information processing device comprising the voltage amplitude detection circuit according to any one of (1) to (11).
(13) A communication device comprising the voltage amplitude detection circuit according to any one of (1) to (11).
(14) A voltage amplitude detection method comprising:

comparing a voltage amplitude of an input signal with a predetermined voltage and output a comparison result;

holding a comparison result output in the comparison step in predetermined periods of a driving clock, and output the held comparison result; and

evaluating a comparison result output in the comparison result holding step in the predetermined periods of the driving clock, and output an evaluation result.

It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2011-283413 filed in the Japan Patent Office on Dec. 26, 2011, the entire content of which is hereby incorporated by reference.

What is claimed is:

1. A voltage amplitude detection circuit comprising:
a first comparison unit configured to compare a voltage amplitude of an input signal with a predetermined voltage and output a comparison result;
a first comparison result holding unit configured to hold the comparison result output from the first comparison unit in predetermined periods of a driving clock, and output the held comparison result; and
a first comparison result evaluation unit configured to evaluate the comparison result output from the first comparison result holding unit in the predetermined periods of the driving clock and output an evaluation result.

2. The voltage amplitude detection circuit according to claim 1, further comprising a delay unit configured to delay the output of the first comparison unit by a predetermined time, and output the delayed output to the first comparison result holding unit and the first comparison result evaluation unit.

3. The voltage amplitude detection circuit according to claim 1, further comprising a delay unit configured to delay the input signal by a predetermined time, and output the delayed input signal to the first comparison result holding unit and the first comparison result evaluation unit.

4. The voltage amplitude detection circuit according to claim 1, further comprising a first frequency dividing unit configured to output the output of the first comparison unit to the first comparison result holding unit and also divide a frequency of the output of the first comparison unit and output the frequency-divided output to the first comparison result holding unit and the first comparison result evaluation unit.

5. The voltage amplitude detection circuit according to claim 4, further comprising:
a second comparison unit configured to compare the voltage amplitude of the input signal with a second predetermined voltage that is higher than the first predetermined voltage and output a comparison result;
a second comparison result holding unit configured to hold the comparison result output from the second comparison unit in predetermined periods of a driving clock and output the held comparison result; and
a second comparison result evaluation unit configured to evaluate the comparison result output from the second comparison result holding unit in the predetermined periods of the driving clock and output an evaluation result,
wherein the first frequency dividing unit divides the frequency of the output of the first comparison unit and output the frequency-divided output to the first comparison result holding unit, the first comparison result evaluation unit, and the second comparison result holding unit.

6. The voltage amplitude detection circuit according to claim 4, further comprising:
a first flip-flop configured to capture an output signal of the first frequency-dividing unit by being driven at a falling edge of the clock;
a second flip-flop configured to capture an output of the first flip-flop; and
a first output evaluation unit configured to evaluate output signals of the first flip-flop and the second flip-flop.

7. The voltage amplitude detection circuit according to claim 6, wherein the first output evaluation unit performs evaluation by calculating exclusive OR of the output signals of the first flip-flop and the second flip-flop.

8. The voltage amplitude detection circuit according to claim 6, further comprising a first noise removing unit configured to remove noise of an output of the first output evaluation unit.

9. The voltage amplitude detection circuit according to claim 6, further comprising:
a second comparison unit configured to compare the voltage amplitude of the input signal with a second predetermined voltage that is higher than the first predetermined voltage, and output a comparison result;
a second comparison result holding unit configured to hold the comparison result output from the second comparison unit in predetermined periods of a driving clock, and output the held comparison result;
a second comparison result evaluation unit configured to evaluate the comparison result output from the second comparison result holding unit in the predetermined periods of the driving clock, and output an evaluation result;
a third flip-flop configured to capture an output signal of the second comparison unit by being driven at a falling edge of the clock;
a fourth flip-flop configured to capture an output of the third flip-flop; and
a second output evaluation unit configured to evaluate output signals of the third flip-flop and the fourth flip-flop.

10. The voltage amplitude detection circuit according to claim 9, wherein the second output evaluation unit performs evaluation by calculating exclusive OR of the output signals of the third flip-flop and the fourth flip-flop.

11. The voltage amplitude detection circuit according to claim 9, further comprising a second noise removing unit configured to remove noise of an output of the second output evaluation unit.

12. An information processing device comprising the voltage amplitude detection circuit according to claim 1.

13. A communication device comprising the voltage amplitude detection circuit according to claim 1.

14. A voltage amplitude detection method comprising:
comparing a voltage amplitude of an input signal with a predetermined voltage and output a comparison result;
holding a comparison result output in the comparison step in predetermined periods of a driving clock, and output the held comparison result; and
evaluating a comparison result output in the comparison result holding step in the predetermined periods of the driving clock, and output an evaluation result.
